(19) United States
(12) Patent Application Publication
(10) Pub. No.: US 2026/0023323 A1
(43) Pub. Date: Jan. 22, 2026

(54) DEVELOPING FLUID SUPPLY APPARATUS, DEVELOPING APPARATUS, AND DEVELOPING FLUID SUPPLY METHOD

(71) Applicant: Tokyo Electron Limited, Tokyo (JP)

(72) Inventors: Kenji IIZUKA, Koshi City (JP); Kouichi MIZUNAGA, Koshi City (JP); Koji USHIMARU, Koshi City (JP); Kazuhiko OOSHIMA, Koshi City (JP); Keigo NAKANO, Koshi City (JP); Yuma TABATA, Koshi City (JP); Masashi TSUCHIYAMA, Koshi City (JP); Ryusei NISHIMURA, Koshi City (JP); Shinsuke TAKAKI, Koshi City (JP)

(21) Appl. No.: 19/268,191

(22) Filed: Jul. 14, 2025

(30) Foreign Application Priority Data
Jul. 19, 2024 (JP) 2024-115679
Mar. 14, 2025 (JP) 2025-041733

(51) Int. Cl. G03F 7/32; G01F 9/00; G03F 7/004

(52) U.S. Cl. CPC G03F 7/32; G01F 9/001; G03F 7/0042

(57) ABSTRACT

A developing fluid supply apparatus comprises a supply path connected to a developing part configured to develop a substrate on which a metal-containing resist film has been formed and which has been subjected to exposure processing, with a developing fluid containing at least one of gas and mist of a weak acid, a developing fluid generator configured to generate the developing fluid from a developing liquid; and a heating part configured to heat the developing fluid to be supplied to the developing part via the supply path.

### CROSS REFERENCE TO RELATED APPLICATIONS

This application is based upon and claims the benefit of priority of the prior Japanese Patent Application No. 2024-115679, filed in Japan on Jul. 19, 2024 and the prior Japanese Patent Application No. 2025-41733, filed in Japan on Mar. 14, 2025, the entire contents of which are incorporated herein by reference.

### TECHNICAL FIELD

This disclosure relates to a developing fluid supply apparatus, a developing apparatus, and a developing fluid supply method.

### BACKGROUND

A substrate treatment system disclosed in Japanese Laid-open Patent Publication No. 2024-17881 includes a wet treatment system, a dry treatment system, and a relay transfer system. The wet treatment system has a wet treatment apparatus configured to perform in a wet mode one of substrate treatments from a formation treatment of a resist film on a substrate to a developing treatment of the resist film after exposure, and is coupled to an exposure apparatus. The dry treatment system has a dry treatment apparatus configured to perform, in a dry mode, the same kind of substrate treatment as that by the wet treatment apparatus. The relay transfer system transfers the substrate between the wet treatment system and the dry treatment system. In the substrate treatment system, when viewed from a coupling direction of the wet treatment system and the exposure apparatus, the wet treatment system is arranged such that the exposure apparatus projects from one side in a depth direction perpendicular to the coupling direction in top view, and the dry treatment system is arranged to be adjacent to the one side of the wet treatment system in the depth direction.

### SUMMARY

An aspect of this disclosure is a developing fluid supply apparatus comprising: a supply path connected to a developing part configured to develop a substrate on which a metal-containing resist film has been formed and which has been subjected to exposure processing, with a developing fluid containing at least one of gas and mist of a weak acid; a developing fluid generator configured to generate the developing fluid from a developing liquid; and a heating part configured to heat the developing fluid to be supplied to the developing part via the supply path.

### BRIEF DESCRIPTION OF THE DRAWINGS

FIG. 1 is a plan view schematically illustrating the outline of a configuration of a wafer treatment system as a developing apparatus according to an embodiment.

FIG. 2 is a front view schematically illustrating the outline of the configuration of the wafer treatment system as the developing apparatus according to the embodiment.

FIG. 3 is a longitudinal sectional view schematically illustrating the outline of a configuration of a developing unit.

FIG. 4 is a transverse sectional view schematically illustrating the outline of the configuration of the developing unit.

FIG. 5 is a longitudinal sectional view schematically illustrating the outline of a configuration of a heat treatment part

FIG. 6 is a plan view schematically illustrating the outline of an arrangement of heaters in a hot plate.

FIG. 7 is a plan view schematically illustrating the outline of a configuration on an upper surface side of the hot plate.

FIG. 8 is a partially enlarged sectional view schematically illustrating the outline of a configuration of a peripheral portion of the hot plate.

FIG. 9 is a diagram for explaining a configuration of a supply mechanism for a developing fluid.

FIG. 10 is a diagram for explaining an example of an arrangement of a supply mechanism.

FIG. 11 is a diagram for explaining an example of the arrangement of the supply mechanism.

FIG. 12 is a flowchart illustrating main processes of Example 1 of a treatment sequence.

FIG. 13 is a flowchart illustrating main processes of Example 2 of the treatment sequence executed by the wafer treatment system.

FIG. 14 is a flowchart illustrating main processes of Example 3 of the treatment sequence executed by the wafer treatment system.

FIG. 15 is a flowchart illustrating main processes of Example 4 of the treatment sequence executed by the wafer treatment system.

FIG. 16 is a diagram for explaining Other example 1 of the supply mechanism for the developing fluid.

FIG. 17 is a diagram for explaining Other example 2 of the supply mechanism for the developing fluid.

FIG. 18 is a view for explaining another example of the method of discharging gas at a low temperature from a discharge port of a hot plate.

FIG. 19 is a view for explaining another example of the method of weakening the development with a developing fluid at the development.

FIG. 20 is a view for explaining an example of gas discharged from the discharge port of the hot plate.

FIG. 21 is a flowchart illustrating main processes of an example of the treatment sequence when a cleaning fluid is discharged from the discharge port of the hot plate.

FIG. 22 is a longitudinal sectional view for explaining another example of a vaporizer.

FIG. 23 is a view illustrating an arrangement example of various units in the second block G2 and an arrangement example of an expansion block.

FIG. 24 is a side view illustrating a configuration example of the expansion block.

FIG. 25 is a partially enlarged rear view illustrating a configuration example of the expansion block, illustrating a state where a rear panel and a unit are detached.

FIG. 26 is a partially enlarged sectional view illustrating a configuration example of the expansion block, illustrating the state where a unit is detached.

FIG. 27 is a view for explaining an example of the maintenance of the developing unit in the case where the expansion block in FIG. 23 is provided.

FIG. 28 is a view for explaining an example of maintenance of the developing unit in the case where the expansion block in FIG. 23 is provided.

FIG. 29 is a view for explaining an example of maintenance of the developing unit in the case where the expansion block in FIG. 23 is provided.

FIG. 30 is a view for explaining an example of maintenance of the developing unit in the case where the expansion block in FIG. 23 is provided.

FIG. 31 is a view illustrating another arrangement example of the units in the second block and Other arrangement example 1 of the expansion block.

FIG. 32 is a side view illustrating another configuration example of the expansion block.

FIG. 33 is a top view illustrating an internal configuration of the expansion block in FIG. 32, illustrating a state where a casing is detached.

FIG. 34 is a view illustrating a state where a mounting part in the expansion block in FIG. 32 is located at a periodical maintenance position.

FIG. 35 is a view illustrating a state where the mounting part in the expansion block in FIG. 32 is located at a heavy maintenance position.

FIG. 36 is a view illustrating another configuration example of the wafer treatment system and Other arrangement example 2 of the expansion block.

FIG. 37 is a view illustrating another example of the wafer treatment system and an arrangement example of the expansion block in the wafer treatment system.

FIG. 38 is a view illustrating another arrangement example of the expansion block to the treatment station in FIG. 37.

### DETAILED DESCRIPTION

Hereinafter, a wafer treatment system as a developing apparatus and a developing fluid supply apparatus according to this embodiment will be explained with reference to the drawings. Note that the same codes denote components having substantially the same functional configurations in this description and the drawings to omit duplicate explanations.

### <Wafer Treatment System>

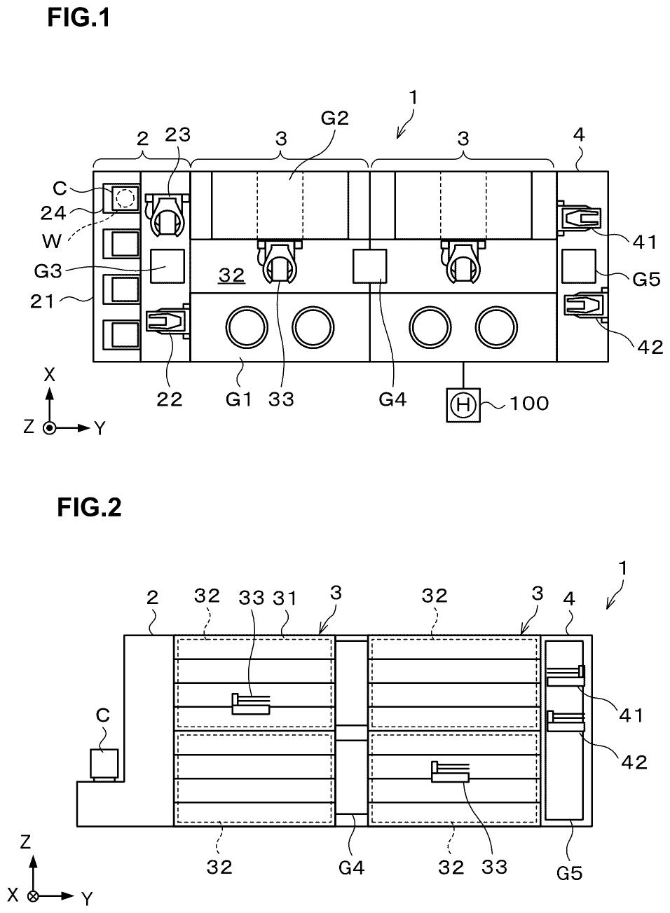

First, a configuration of the wafer treatment system as the developing apparatus according to this embodiment will be explained. FIG. 1 and FIG. 2 are a plan view and a front view schematically illustrating the outline of a configuration of a wafer treatment system 1, respectively. In this embodiment, a case where the wafer treatment system 1 is a photolithography processing system which performs a forming treatment and a developing treatment of a resist film on a semiconductor wafer (hereinafter, hereinafter referred to as a “wafer”) W as a substrate will be explained as an example.

The wafer treatment system 1 has a cassette station 2 into/out of which a cassette C housing a plurality of wafers W is carried, and a treatment station 3 including a plurality of various treatment apparatuses which perform predetermined treatments on the wafer Was illustrated in FIG. 1. The wafer treatment system 1 has a configuration in which the cassette station 2, the treatment station 3, and an interface station 4 which delivers the wafer W between the treatment station 3 and an exposure apparatus (not illustrated) adjacent to a side opposite to the treatment station 3 are integrally connected. Note that two treatment stations 3 are installed between the cassette station 2 and the interface station 4 as illustrated in FIG. 1, but one or three or more treatment stations 3 may be installed.

In the cassette station 2, a cassette stage 21, a wafer carrier apparatus 22, and a wafer carrier apparatus 23 are provided. On the cassette stage 21, a plurality of cassette stage plates 24 are arranged. In the cassette station 2, the wafer carrier apparatus 22 or the wafer carrier apparatus 23 carries the wafer between the cassette C mounted on the cassette stage 21 and the treatment station 3. Therefore, each of the wafer carrier apparatus 22 and the wafer carrier apparatus 23 is provided with a drive mechanism having a movement path in each of horizontal directions (X-direction and Y-direction) and an up-down direction (Z-direction) and around a vertical axis (in a θ-direction) as necessary, and may be provided with a drive mechanism having movement paths in all directions.

At least any of the wafer carrier apparatus 22 and the wafer carrier apparatus 23 can deliver the cassette C and the wafer W, and can perform a delivery operation of the wafer to/from the treatment station 3. Note that the delivery operation of the wafer W to/from the treatment station 3 means, for example, delivery of the wafer to/from a third block G3 including a delivery apparatus accessible by a wafer carrier apparatus 33 in the later-explained treatment station 3. The third block G3 may include a plurality of delivery apparatuses (not illustrated) lined up in the up-down direction.

Note that an inspection apparatus (not illustrated) which performs inspection on the wafer W may be provided at a position accessible by any of the wafer carrier apparatus 22 and the wafer carrier apparatus 23.

In the treatment station 3, a plurality of blocks, for example, three blocks such as first, second, and fourth blocks G1, G2, G4 are provided. Further, as illustrated in FIG. 2, a plurality of layers 31 including the first and second blocks G1, G2 are stacked in the up-down direction. For example, the first block G1 is provided on the front side (X-direction negative direction side in FIG. 1) in the treatment station 3, and the second block G2 is provided on the rear side (X-direction positive direction side in FIG. 1) in the treatment station 3. The fourth block G4 is provided on the interface station 4 side (Y-direction positive direction side in FIG. 1) in the treatment station 3 or at a connection portion with adjacent another treatment station 3. The fourth block G4 may include a plurality of delivery apparatuses lined up in the up-down direction. Besides, the above third block G3 may be provided in the treatment station 3.

In the first block G1, a plurality of treatment apparatuses, for example, patterning film forming apparatuses and a developing treatment apparatus which are not illustrated are arranged. As the patterning film forming apparatuses, for example, an anti-reflection film forming apparatus can be included in addition to a resist film forming apparatus.

For example, the plurality of treatment apparatuses are arranged side by side in the horizontal direction in the first block G1. Note that the numbers, arrangements, and types of these treatment apparatuses in the first block G1 can be arbitrarily selected.

In the patterning film forming apparatuses and the developing treatment apparatus, for example, supply of predetermined treatment solutions or supply of predetermined gases onto the wafer W is performed. In this manner, the formation of a resist film to be used as a mask when forming a pattern of a film on the lower layer side and the formation of an anti-reflection film for efficiently performing light irradiation processing, for example, exposure processing are performed in the patterning film forming apparatuses. On the other hand, a concave and convex shape as the above mask is formed by removing a part of the exposed resist film in the developing treatment apparatus.

For example, in the second block G2, thermal treatment apparatuses (not illustrated) which perform thermal treatments such as heating and cooling of the wafer W are provided side by side in the up-down direction and the horizontal direction. Further, in the second block G2, not-illustrated hydrophobization treatment each apparatuses for performing a hydrophobization treatment in order to enhance the fixation between a resist solution and the wafer W and not-illustrated edge exposure apparatuses each for exposing an outer peripheral portion of the wafer W are provided side by side in the up-down direction (Z-direction) and the horizontal direction. The numbers and arrangements of the thermal treatment apparatuses, the hydrophobization treatment apparatuses, and the edge exposure apparatuses can also be arbitrarily selected.

As illustrated in FIG. 1, in a region sandwiched between the first block G1 and the second block G2 in plan view, a wafer carry region 32 is formed. In the wafer carry region 32, for example, the wafer carrier apparatus 33 is arranged.

The wafer carrier apparatus 33 has a carrier arm movable, for example, in the Y-direction, the front-rear direction, the θ-direction, and the Z-direction. The wafer carrier apparatus 33 can move in the wafer carry region 32 to carry the wafer W to predetermined apparatuses in the first block G1, the second block G2, the third block G3, and the fourth block G4 therearound. In the case where the plurality of treatment stations 3 exist as in FIG. 1, the wafer carrier apparatus 33 provided in the treatment station 3 located on the interface station 4 side can carry the wafer W to predetermined apparatuses in a later-explained fifth block G5 in addition to the first, second, and fourth blocks G1, G2, G4.

A plurality of the wafer carrier apparatuses 33 are provided, for example, one above the other as illustrated in FIG. 2. One wafer carrier apparatus 33 can carry the wafer W to predetermined apparatuses located at heights of the plurality of layers 31 on the upper side of the plurality of layers 31 stacked one on top of the other. The other wafer carrier apparatus 33 can carry the wafer W to predetermined apparatuses located at heights of the plurality of layers 31 located below the layers 31 on the upper side. A plurality of the wafer carry regions 32 are provided in a manner to enable such carriage of the wafer W. Note that the number of the wafer carrier apparatuses 33 and the number of the layers 31 corresponding to one wafer carrier apparatus 33 can be arbitrarily selected, for instance by providing the wafer carrier apparatus 33 for each layer 31.

Further, in the wafer carry region 32, or the first block G1 or the second block G2, a shuttle carrier apparatus (not illustrated) may exist. The shuttle carrier apparatus linearly carries the wafer W between a space adjacent to one of the treatment stations 3 and another space adjacent to the side opposite thereto.

In the interface station 4, the fifth block G5 including a plurality of delivery apparatuses, a wafer carrier apparatus 41, and a wafer carrier apparatus 42 are provided. The interface station 4 carries the wafer W using the wafer carrier apparatus 41 or the wafer carrier apparatus 42 between the fifth block G5 to/from which the wafer W is delivered by the wafer carrier apparatus 33 and the exposure apparatus. Therefore, the wafer carrier apparatus 41 and the wafer carrier apparatus 42 each have a drive mechanism having a movement path in each of directions such as the horizontal directions (X-direction and Y-direction) and the up-down direction (Z-direction) and around the vertical axis (in a θ-direction) as necessary, and may include a drive mechanism having movement paths in all directions. At least any of the wafer carrier apparatus 41 and the wafer carrier apparatus 42 can support the wafer W and carry the wafer W between the delivery apparatus in the fifth block G5 and the exposure apparatus.

A cleaning apparatus which cleans the front surface of the wafer W and the above edge exposure apparatus may be provided at positions accessible by any of the wafer carrier apparatus 41 and the wafer carrier apparatus 42 in the interface station 4.

The inspection apparatus may be provided in the cassette station 2 as explained above, but may be provided at a position accessible by any of the carrier arms (of the wafer carrier apparatuses 33, 41, 42 in FIG. 1 or FIG. 2) provided in the treatment station 3 and the interface station 4, respectively.

In the above wafer treatment system 1, at least one controller 100 is provided. The controller 100 processes computer-executable instructions causing the wafer treatment system 1 to execute various processes explained in this disclosure. The controller 100 can be configured to control components in the wafer treatment system 1 so as to execute the various processes explained herein. In one embodiment, part or whole of the controller 100 may be included in the wafer treatment system 1. The controller 100 may include a processor, a storage, and a communication interface. The controller 100 is implemented, for example, by a computer. The processor can be configured to read from the storage a program which provides a logic or routine enabling performance of various control operations and execute the read program to thereby perform the various control operations. This program may be stored in the storage in advance, or acquired via a medium when required. The acquired program is stored in the storage, and read out of the storage and executed by the processor. The medium may be various computer-readable storage media H or may be a communication line connected to the communication interface. The storage medium may be a transitory one or a non-transitory one. The processor may be a CPU (Central Processing Unit), or may be one or a plurality of circuits. The storage may include a RAM (Random Access Memory), a ROM (Read Only Memory), an HDD (Hard Disk Drive), an SSD (Solid State Drive), or a combination of them. The communication interface may communicate with the wafer treatment system 1 via a communication line such as a LAN (Local Area Network).

Note that the wafer treatment system in this disclosure is not limited to the above-explained configuration. For example, the wafer treatment system is directly connected to the exposure apparatus and delivers the wafer W between the interface station 4 and the exposure apparatus in the above embodiment, but the wafer treatment system does not need to be directly connected to the exposure apparatus. In this case, for example, the wafer W is carried from the cassette station 2 to the treatment station 3 and subjected to required treatments and then carried again to the cassette station 2 to be carried to the outside of the system.

Further, the one among the listed treatment apparatuses that is not required does not need to be provided in the wafer treatment system, or the treatment in that apparatus does not need to be performed.

### <Type of the Resist>

In the wafer treatment system 1 in this disclosure, a coating film of the resist to be formed on the wafer W by the resist film forming apparatus, namely, a resist film is a coating film of a metal-containing resist, namely, a metal-containing resist film.

Note that the metal-containing resist contains metal as a constituent of the resist, but does not mean a resist containing metal only as an impurity.

The metal-containing resist is a material of the resist film to be formed on the front surface of the substrate and contains ligand-bound metal.

The metal being the constituent of the resist may be selected from, but not limited to, the group consisting of, for example, tin (Sn), tungsten (W), hafnium (Hf), zirconium (Zr), indium (In), tellurium (Te), antimony (Sb), nickel (Ni), cobalt (Co), titanium (Ti), tantalum (Ta), molybdenum (Mo), bismuth (Bi), iodine (I), germanium (Ge), and a combination of them, and is not limited to those listed here.

A reaction example of the metal-containing resist is that the binding of metals to a ligand is cut (namely, a ligand is released) and then the metals undergo a condensation reaction and are bound with each other via oxygen atoms into a state of an oxide. The metals in the state of the oxide are a compound stronger than before becoming the oxide. The release of the ligand proceeds mainly by the exposure and the condensation reaction proceeds mainly by the heating after the exposure, resulting in that the above metals becoming the oxide are present in the resist film.

### <Developing Unit 200>

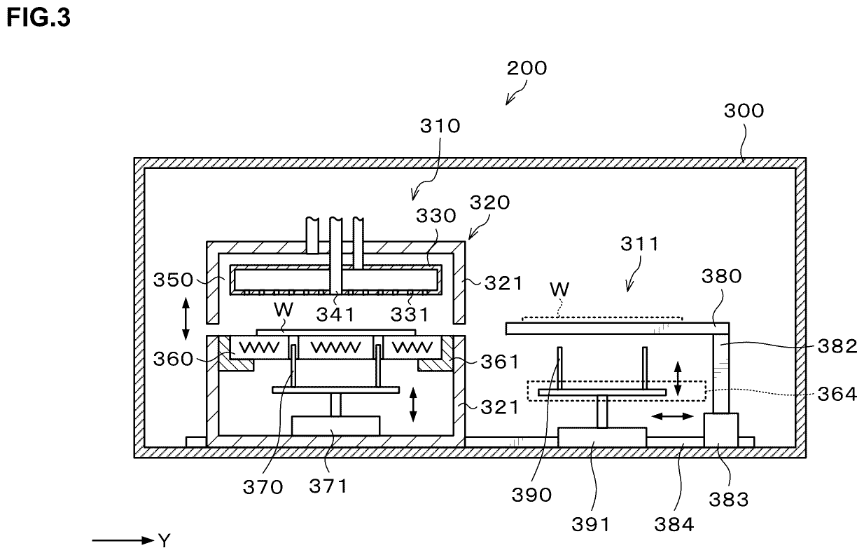

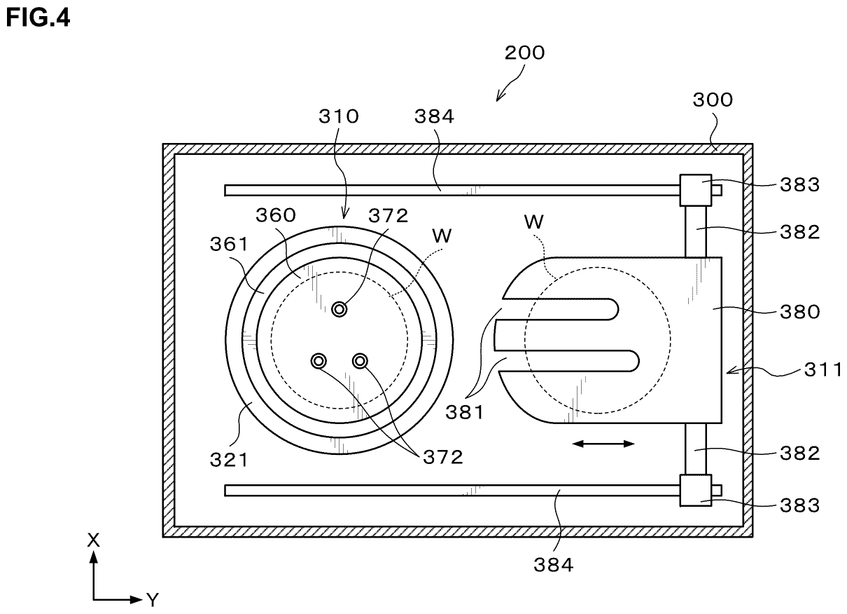

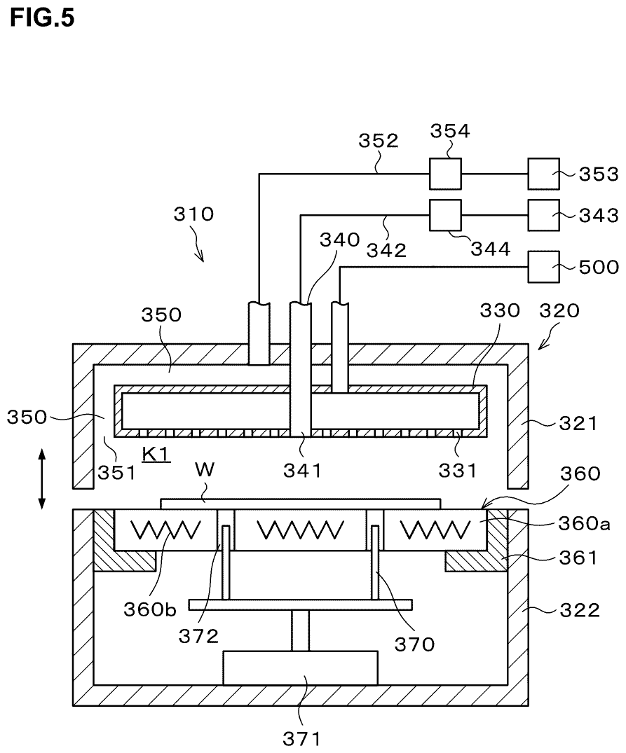

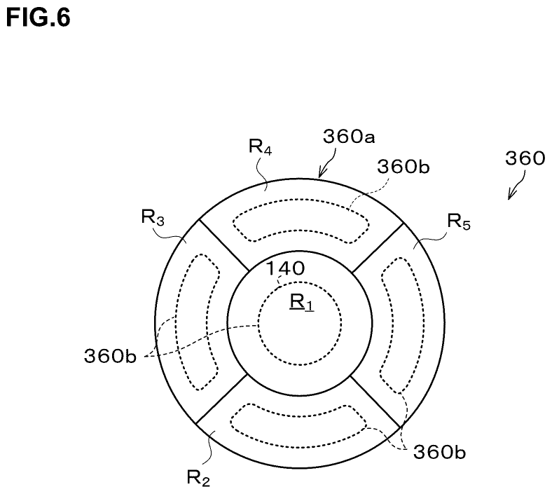

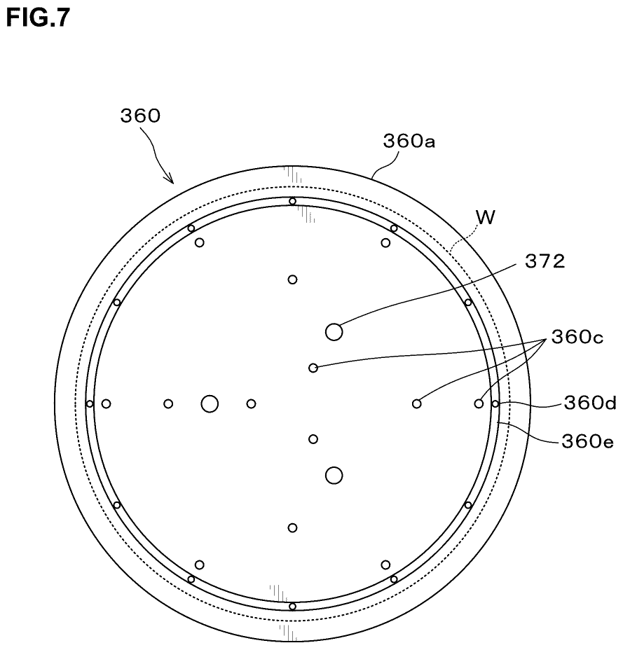

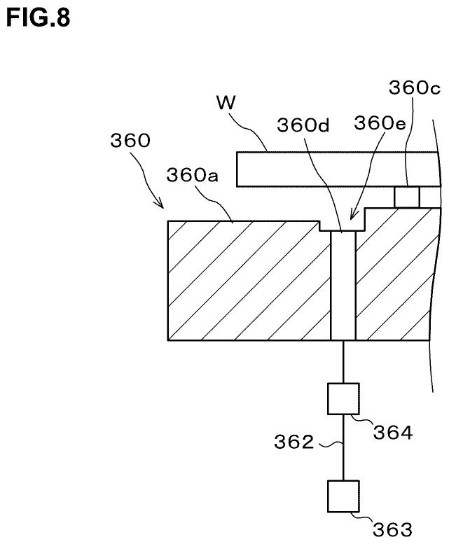

Next, the developing unit 200 as the developing part according to this disclosure will be explained. FIG. 3 and FIG. 4 are a longitudinal sectional view and a transverse sectional view schematically illustrating the outline of a configuration of the developing unit 200. FIG. 5 is a longitudinal sectional view schematically illustrating the outline of a configuration of a later-explained heat treatment part 310. FIG. 6 is a plan view illustrating the outline of the arrangement of heaters in a later-explained hot plate 360. FIG. 7 is a plan view schematically illustrating the outline of a configuration on the upper surface side of the hot plate 360. FIG. 8 is a partially enlarged sectional view schematically illustrating the outline of a configuration of a peripheral portion of the hot plate 360.

The developing unit 200 in FIG. 3 and FIG. 4 develops the wafer W on which the coating film of the resist has been formed and which has been subjected to exposure processing, with a developing fluid containing gas of a weak acid. Specifically, the developing unit 200 develops the wafer W on which the coating film of the metal-containing resist has been formed and which has been subjected to the exposure processing and the heat treatment after the exposure (PEB treatment), with a developing fluid containing gas of a weak acid. The exposure processing here is processing of transferring a pattern of a mask by exposure performed in the exposure apparatus.

The developing unit 200 is provided, for example, in the same block with the thermal treatment apparatus which performs a thermal treatment such as a heat treatment on the wafer W, namely, the second block G2 in the wafer treatment system 1.

The developing unit 200 has a treatment container 300 whose inside is sealable. At a side surface on a wafer carry region side (a side of a region where the wafer carrier apparatus 33 is provided) in the treatment container 300, a carry-in/out port (not illustrated) for the wafer W is formed, and an opening/closing shutter (not illustrated) is provided at the carry-in/out port.

Inside the treatment container 300, a heat treatment part 310 which performs a treatment with heating on the wafer W and a temperature regulation part 311 which regulates the temperature of the wafer W are provided. The heat treatment part 310 and the temperature regulation part 311 are arranged side by side in the Y-direction, and the temperature regulation part 311 is provided on a side closer to the carry-in/out port than the heat treatment part 310.

As illustrated in FIG. 5, the heat treatment part 310 has a chamber 320 which forms a treatment space K1 for housing the wafer W and is provided with a discharge port 331 for discharging a developing fluid to the treatment space K1. The chamber 320 has an upper chamber 321 which is located on the upper side and freely raised and lowered, and a lower chamber 322 which is located on the lower side and integrated with the upper chamber 321 to be able to seal the inside.

The upper chamber 321 is configured to be freely raised and lowered by a raising and lowering mechanism (not illustrated). The raising and lowering mechanism has a driving source (not illustrated) such as a motor which generates a driving force for raising and lowering the upper chamber 321. The raising and lowering mechanism is controlled by the controller 100.

The upper chamber 321 is formed, for example, in an almost cylindrical shape with a lower surface open. Inside the upper chamber 321 and at a position facing the later-explained hot plate 360, a shower head 330 as a gas discharger is provided. The shower head 330 is configured to be freely raised and lowered in synchronization with the upper chamber 321.

The lower surface of the shower head 330 is formed with a plurality of discharge ports 331 for discharging the developing fluid containing gas of a weak acid to the treatment space K1. Each of the discharge ports 331 discharges the developing fluid containing the gas of the weak acid from above the hot plate 360 toward the hot plate 360. The gas of the weak acid is, for example, gas of a carboxylic acid being a weak acid. The gas of the carboxylic acid being the weak acid may be, for example, vapor of acetic acid. The “weak acid” in this disclosure means an acid having a value of an acid dissociation constant (pka) of 4 or more (for example, about 5). Further, the developing fluid containing the gas of the weak acid contains, for example, a vaporized substance, namely, vapor of a mixed solution of the carboxylic acid being the weak acid and an organic solvent and a carrier gas. Besides, the developing fluid containing the gas of the weak acid may be the one containing a vaporized substance from the carboxylic acid being the weak acid alone and a carrier gas. The carboxylic acid being the weak acid is specifically, for example, acetic acid. The organic solvent is, for example, propylene glycol monomethyl ether acetate (PGMEA). The carrier gas is, for example, an inert gas such as a nitrogen gas or an argon (Ar) gas.

A plurality of discharge ports 331 are uniformly arranged at a portion other than a later-explained exhaust port 341 in the lower surface of the shower head 330. To the shower head 330, a supply mechanism 500 for the developing fluid containing the gas of the weak acid, as the developing fluid supply apparatus.

The shower head 330 is formed with a central exhaust path 340 which extends upward from the exhaust port 341 formed at a lower surface central portion of the shower head 330. To the central exhaust path 340, an exhaust apparatus 343 such as a vacuum pump is connected through an exhaust pipe 342. Further, the exhaust pipe 342 is provided with an exhaust equipment group 344 having a valve and so on which adjust the exhaust rate. The exhaust apparatus 343 and the exhaust equipment group 344 are controlled by the controller 100. Note that in this embodiment, the central exhaust path 340, the exhaust pipe 342, the exhaust apparatus 343, and the exhaust equipment group 344 constitute a central exhauster according to this disclosure which exhausts the inside of the treatment space K1 from a position close to the center in a top view of the wafer W on the hot plate 360.

Inside the upper chamber 321, an outer peripheral exhaust path 350 extending from an exhaust port 351 opening downward in a manner to surround the outer periphery of the shower head is formed. To the outer peripheral exhaust path 350, an exhaust apparatus 353 such as a vacuum pump is connected through an exhaust pipe 352. Further, the exhaust pipe 352 is provided with an exhaust equipment group 354 having a vale and so on which adjust an exhaust rate. Note that in this embodiment, the outer peripheral exhaust path 350, the exhaust pipe 352, the exhaust apparatus 353, and the exhaust equipment group 354 constitute an outer peripheral exhauster according to this disclosure which exhausts the inside of the treatment space K1 from a side closer to the peripheral portion of the wafer W on the hot plate 360 than the central exhauster in a top view.

The lower chamber 322 has an almost cylindrical shape with an upper surface open. At an upper surface opening of the lower chamber 322, the hot plate 360 and a holding member 361 in a ring shape for accommodating the hot plate 360 and holding the peripheral portion of the hot plate 360 are provided. The hot plate 360 has a thick and almost circular plate shape and can support the wafer W in the treatment space K1 and heat the wafer W located above the hot plate 360.

The hot plate 360 has a main body part 360a formed in a plate shape (specifically, a circular plate shape) and having heaters 360b embedded therein. The heater 360b is, for example, a resistance heating heater. The temperature of the hot plate 360 (specifically, the temperature of the main body part 360a) is adjusted by the control of the heater 360 by the controller 100, and thus, for example, the wafer W supported by the hot plate 360 or otherwise and thereby located above the hot plate 360 is heated to a predetermined temperature.

The hot plate 360 may be configured to be able to heat the wafer W so that the heating amount of the wafer W differs in a radial direction and a circumferential direction of the wafer W. Specifically, the hot plate 360 may be configured as illustrated in FIG. 6.

The hot plate 360 (specifically, the main body part 360a) in FIG. 6 is partitioned into a plurality of, for example, five regions R₁ to R₅. The region R₁ is a circular region provided at the central portion of the hot plate 360 in plan view. The regions R₂ to R₅ are arc-shaped regions obtained by dividing an annular region located outside the region R₁ in plan view into four equal parts. Assuming that the region R₁ is a first region and the annular region of the regions R₂ to R₅ is a second region, the first region and the second region are arranged concentrically with the hot plate 360.

In each of the regions R₁ to R₅ of the hot plate 360, the heater 360b is individually built in. The heater 360b can individually heat each of the regions R₁ to R₅. Further, in each of the regions R₁ to R₅, a temperature sensor (not illustrated) may be individually provided. The temperature sensor individually measures the temperature of each of the regions R₁ to R₅ where the temperature sensor is provided. The heating value of the heater 360b in each of the regions R₁ to R₅ is adjusted, for example, by the controller 100 so that the temperature measured by each temperature sensor becomes a set temperature for each of the regions R₁ to R₅.

Note that the numbers and arrangement of the regions partitioned in the hot plate 360 can be arbitrarily selected.

Further, at the main body part 360a of the hot plate 360, a plurality of protrusions 360c are provided in a manner to protrude from its upper surface to support the wafer W as illustrated in FIG. 7 and FIG. 8. The plurality of protrusions 360c are provided at, for example, the following positions.

The upper surface is partitioned into a plurality of regions along a radial direction of the upper surface of the main body part 360a (namely, the radial direction of the wafer W supported by the hot plate 360), and the protrusion 360c is provided in each of the regions. Specifically, the protrusion 360c is provided in each of a plurality of (three or more) portions different from each other in position relating to the circumferential direction of the upper surface in each region.

Further, the main body part 360a is formed with a discharge port 360d for discharging an inert gas (nitrogen gas or the like) as a predetermined gas. The discharge port 360d discharges the inert gas toward a rear surface of the wafer W supported by the hot plate 360 or otherwise and thereby located above the hot plate 360 in the treatment space K1, specifically, discharges the inert gas toward a rear surface peripheral portion of the wafer W. This can suppress, for example, the adhesion of a substance produced at the time of development (hereinafter, a development-time product) such as a sublimate produced from the metal-containing resist film during development, to the rear surface peripheral portion of the wafer W.

The discharge port 360d is provided, specifically, at a bottom portion of a groove 360e in a ring shape in plan view (specifically, in a circular ring shape in plan view) formed at the upper surface of the main body part 360a.

To the discharge port 360d, a supply mechanism 363 for the inert gas is connected through a supply path 362. The supply mechanism 363 has, for example, a supply source of the inert gas and a supply equipment group including an opening/closing valve and a flow rate regulating valve for controlling the distribution of the inert gas, which are not illustrated. The supply equipment group is controlled by the controller 100. The supply path 362 is provided with a heat exchanger 364 as a heating part which heats the gas discharged from the discharge port 360d, outside the chamber 320 and outside the hot plate 360. The heat exchanger 364 is controlled by the controller 100. Further, the heat exchanger 364 is provided, for example, in the treatment container 300 which separates the chamber 320 from the outside (a later-explained vaporizer 501), specifically, below a later-explained temperature regulation plate 380 in a state of being located at an initial position in the treatment container 300 as illustrated in FIG. 3. The gas discharged from the discharge port 360d is heated to be higher in temperature than at least the wafer W by the heat exchanger 364.

Note that not the supply mechanism 363 but the supply mechanism for the inert gas in the supply mechanism 500 may be connected to the discharge port 360d. In other words, the inert gas to be used in the supply mechanism 500 may be used for the inert gas to be discharged from the discharge port 360d.

With a larger number of the discharge ports 360d, the inert gas can be more uniformly supplied in the circumferential direction of the hot plate 360 (namely, the circumferential direction of the wafer W supported by the hot plate 360), whereas with a smaller number of the discharge ports 360d, less influence of the discharge ports 360d is exerted on the temperature distribution of the hot plate 360. Accordingly, two or more discharge ports 360d are provided intermittently along the groove 360e as illustrated in FIG. 7 to suppress the influence of the discharge ports 360d exerted on the temperature distribution of the hot plate 360, and the width of the groove 360e may be made larger than the diameter (or width) of the discharge port 360d as illustrated in FIG. 8 so that the predetermined gas can be uniformly supplied in the circumferential direction.

The groove 360e is provided, for example, in a region facing the rear surface peripheral portion of the wafer W when supported by the hot plate 360. In this example, the distance from the wafer W when supported by the hot plate 360 (specifically, supported by the protrusion 360c) to the main body part 360a is larger on the outside of the groove 360e than on the inside of the groove 360e. Therefore, it is possible to suppress the flow of the inert gas, which is discharged from the discharge port 360d formed at the bottom portion of the groove 360e, toward the inner side of the groove 360e, and efficiently direct the inert gas toward the peripheral edge of the wafer W supported by the hot plate 360. Accordingly, the inert gas discharged from the discharge port 360d formed at the bottom portion of the groove 360e can efficiently suppress the adhesion of the development-time product to the rear surface peripheral portion of the wafer W.

Note that the main body part 360a of the hot plate 360 may be provided with, for example, a plurality of suction holes (not illustrated) for sucking the wafer W to the hot plate 360.

As illustrated in FIG. 3, for example, three raising and lowering pins 370 as raising and lowering parts which support the wafer W from below and raise and lower the wafer W are provided inside the lower chamber 322 and below the hot plate 360. The raising and lowering pins 370 can move up and down by a raising and lowering drive part 371 having a driving source such as a motor. Near the central portion of the main body part 360a of the hot plate 360, through holes 372 which pass through the main body part 360a in the thickness direction are formed, for example, at three locations. The raising and lowering pins 370 can pass through the through holes 372 and project from the upper surface of the main body part 360a of the hot plate 360.

The temperature regulation part 311 has the temperature regulation plate 380 as illustrated in FIG. 3 and FIG. 4. The temperature regulation plate 380 has an almost square flat shape and its end surface on the hot plate 360 side curves in an arc shape. The temperature regulation plate 380 is formed with two slits 381 along the Y-direction. The slits 381 are formed from the end surface on the hot plate 360 side of the temperature regulation plate 380 to the vicinity of the central portion of the temperature regulation plate 380. The slits 381 can prevent the temperature regulation plate 380 from interfering with the raising and lowering pins 370 and later-explained raising and lowering pins 390. Further, the temperature regulation plate 380 has a built-in temperature regulation member (not illustrated) such as a path of cooling water or a Peltier element. The temperature of the temperature regulation plate 380 is controlled, for example, by the controller 100, and the wafer W placed on the temperature regulation plate 380 is regulated to a predetermined temperature.

The temperature regulation plate 380 is supported by a support arm 382. To the support arm 382, a drive part 383 having a driving source such as a motor is attached. The drive part 383 is attached to a rail 384 extending in the Y-direction. The rail 384 extends from the temperature regulation part 311 to the heat treatment part 310. The drive part 383 can move the temperature regulation plate 380 between the initial position in the temperature regulation part 311 and a delivery position in the heat treatment part 310 along the rail 384.

Note that at the initial position, the wafer W is delivered between the carrier arm of the wafer carrier apparatus 33 and the temperature regulation plate 380 via the later-explained raising and lowering pins 390. Further, at the delivery position, the wafer W is delivered between the hot plate 360 and the temperature regulation plate 380 via the later-explained raising and lowering pins 370.

Below the temperature regulation plate 380, for example, three raising and lowering pins 390 which support the wafer W from below and raise and lower the wafer W are provided. The raising and lowering pins 390 can move up and down by a raising and lowering mechanism 391 having a driving source such as a motor. The raising and lowering pins 390 can pass through the through slits 381 and project from the upper surface of the temperature regulation plate 380.

### <Supply Mechanism 500>

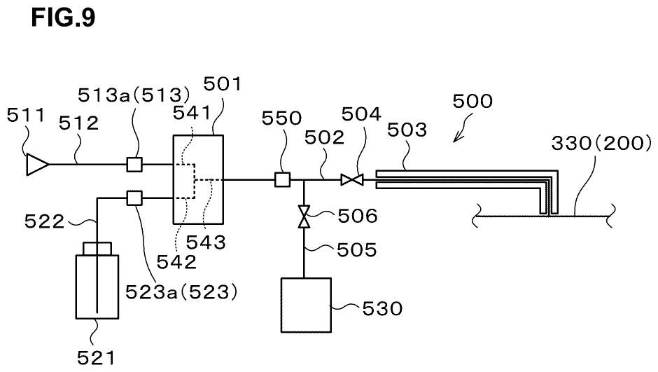

Next, a supply mechanism 500 for the developing fluid will be explained. FIG. 9 is a diagram for explaining a configuration of the supply mechanism 500 for the developing fluid.

The supply mechanism 500 has a vaporizer 501 as a developing fluid generator which generates the developing fluid from a developing liquid, for example, as illustrated in FIG. 9. The vaporizer 501 vaporizes the mixed solution of acid as the developing liquid and an organic solvent to generate the developing fluid. To the vaporizer 501, one end of a supply path 502 is connected. Another end of the supply path 502 is connected to the developing unit 200, specifically, connected to the shower head 330 of the developing unit 200. The supply path 502 is made of a fluorocarbon resin having corrosion resistance against acid. Further, the supply path 502 is provided with a heater 503 which heats the supply path 502, as a heating part which heats the developing fluid to be supplied to the developing unit 200 through the supply path 502. The heater 503 is formed, for example, in a tape shape, namely, is a tape heater which is used wrap around the supply path 502. The heater 503 is controlled by the controller 100. The control of the heater 503 by the controller 100 adjusts the temperature of the developing fluid to be supplied from the supply mechanism 500, specifically, the temperature is adjusted to take a desired value, and more specifically, the temperature is adjusted such that the temperature when the developing fluid reaches the wafer W in the treatment space K1 takes a desired value (for example, equal to the temperature of the wafer W).

The heater 503 is provided at least on the downstream side of the supply path 502. On the upstream of a portion of the supply path 502 where the heater 503 is provided, an opening/closing valve 504 is provided which controls the distribution of the developing gas in the supply path 502. The opening/closing valve 504 is controlled by the controller 100.

To the vaporizer 501, a supply source 511 of an inert gas as a carrier gas is connected through a gas supply path 512. The gas supply path 512 is provided with a supply equipment group 513 including an opening/closing valve for controlling the distribution of the inert gas in the gas supply path 512, a gas flow rate regulating valve 513a for regulating the flow rate of the inert gas, and so on. The supply equipment group 513 is controlled by the controller 100.

Further, to the vaporizer 501, a tank 521 which stores a mixed solution of acid and an organic solvent is connected through a solution supply path 522. The solution supply path 522 is provided with a supply equipment group 523 including an opening/closing valve for controlling the distribution of the mixed solution in the solution supply path 522, a liquid flow rate regulating valve 523a for regulating the flow rate of the mixed solution, and so on. The supply equipment group 523 is controlled by the controller 100. Note that the supply of the mixed solution of the acid and the organic solvent is not limited to that by the tank 521 but may also be that, for example, by a configuration in which, for example, a supply pipe for the mixed solution from a facility in a factory provided with the developing apparatus 30 is connected to the solution supply path 522.

Further, to the supply path 502, a branch path 505 is connected. Specifically, one end of the branch path 505 is connected to a point between the vaporizer 501 and the opening/closing valve 504 on the supply path 502. Another end of the branch path 505 is connected to a drain tank 530 which also functions as a condenser for condensing and liquefying the mixed gas of the acid and the organic solvent contained in the developing fluid. The branch path 505 is provided with an opening/closing valve 506 which controls the distribution of the developing fluid in the branch path 505. The opening/closing valve 506 is controlled by the controller 100.

In the supply mechanism 500, for example, the vaporizer 501 continuously generates the developing fluid at all times, and the generated developing gas is made to flow toward the branch path 505 when not supplied to the developing unit 200.

The vapor, namely, gas of the mixed solution of the acid and the organic solvent contained in the developing fluid made flow toward the branch path 505 is cooled and liquefied again and stored in the drain tank 530. The mixed solution stored in the drain tank 530 may be returned to the tank 521. In other words, the mixed solution may be circulated.

Further, the vaporizer 501 has a flow path 541 through which an inert gas flows, a flow path 542 through which the mixed solution flows, and a flow path 543 through which a mixed fluid obtained by mixing the inert gas and the mixed solution flows and in which the mixed fluid is heated and the mixed solution is vaporized.

Further, the vaporizer 501 has an inner wall surface of the flow path through which (liquid of) acid or vapor of acid flows and which is made of a nickel-chromium alloy, silicon, or a silicon compound having corrosion resistance against acid. Specifically, in the vaporizer 501, for example, members forming the flow paths 541, 542, 543 are made of a nickel-chromium alloy, silicon, or a silicon compound.

The supply mechanism 500 further has a concentration sensor 550 which measures the concentration of the weak aid in the developing fluid. The concentration sensor 550 is installed, for example, between the vaporizer 501 and the opening/closing valve 504 in the supply path 502. A measurement result by the concentration sensor 550 is sent to the controller 100. The control by the controller 100 based on the measurement result by the concentration sensor 550 adjusts the concentration of the weak aid in the developing fluid supplied from the supply mechanism 500, specifically, adjusts the concentration to a desired value. In the supply mechanism 500, the concentration of the weak acid in the developing fluid can be regulated, for example, by the heating temperature of the mixed solution in the vaporizer 501 (specifically, the heating temperature of the mixed fluid in the flow path 543 in the vaporizer 501), the supply flow rate of the mixed solution to the vaporizer 501, or the supply flow rate of the inert gas as the carrier gas to the vaporizer 501.

At least a part of the supply mechanism 500 is provided, for example, adjacent to the developing unit 200 to which the developing fluid is supplied. Specifically, a part including the vaporizer 501 in the supply mechanism 500 is provided adjacent to the developing unit 200 to which the developing fluid is supplied.

The developing apparatus according to this embodiment includes at least the vaporizer 501 of the supply mechanism 500 and the above developing unit 200.

### <Arrangement of the Supply Mechanism 500>

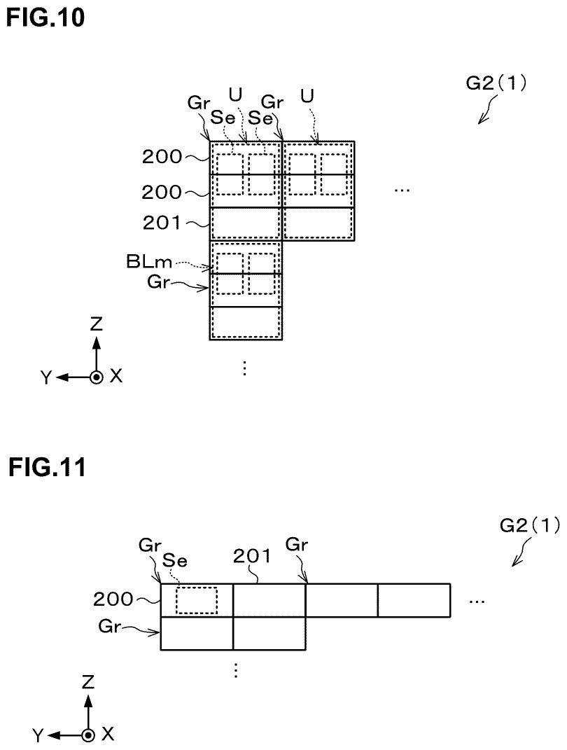

FIG. 10 and FIG. 11 are diagrams each for explaining an example of the arrangement of the supply mechanism 500 and illustrate the rear surface (surface on the X-direction positive side) of the second block G2 in the wafer treatment system. A set Se of the vaporizer 501 of the supply mechanism and the concentration sensor 550 corresponding to the vaporizer 501 may be configured to be provided at a height corresponding to the developing unit 200, namely, at the same height as the developing unit 200 so as to face the developing unit 200 at the supply destination of the developing fluid. Further, the set Se may be configured to be provided adjacent to the developing unit 200 at the supply destination of the developing fluid.

In the second block G2 of the wafer treatment system 1, for example, two stacked developing units 200 and an electrical unit 201 on which the two developing units 200 are stacked and which is common to the two developing units 200 are assumed to be one combination unit Gr, as illustrated in FIG. 10. A plurality of the combination units G are arranged in each of the horizontal direction and the height direction. In this case, the sets Se each corresponding to the two developing units 200 included in one unit U may be collected into one common block BLm and provided adjacent to the rear surface (surface on the X-direction positive side) of the combination unit Gr. This can improve the controllability and the responsiveness of the concentration in the developing fluid and the flow rate of the developing fluid to be supplied to the developing units 200. Further, the unit U is preferably provided such that the sets of the vaporizers 501 and the concentration sensors 550 included in the unit U face not the electrical units 201 but the developing units 200 at the supply destinations.

Besides, in the second block G2 of the wafer treatment system 1, for example, one developing unit 200 and an electrical unit 201 arranged side by side in the horizontal direction with the developing unit 200 and corresponding to the developing unit 200 are assumed to be one combination unit Gr as illustrated in FIG. 11, and a plurality of the combination units Gr may be arranged in each of the horizontal direction and the height direction. In this case, the set Se corresponding to the developing unit 200 included in the one combination unit Gr may be provided adjacent to the rear surface (surface on the X-direction positive side) of the combination unit Gr. This can also improve the controllability and the responsiveness of the concentration in the developing fluid and the flow rate of the developing fluid to be supplied to the developing unit 200. Further, in this case, the set Se of the vaporizer 501 and the concentration sensor 550 is preferably provided such that the set Se face not the electrical unit 201 but the developing unit 200 at the supply destination.

Furthermore, an expansion block housing the above set Se of the supply mechanism 500 may be configured to be partially detachable and movable. In this case, by partially detaching or moving the expansion block, the developing unit 200 at the supply destination of the developing fluid by the supply mechanism 500 can be subjected to maintenance. In other words, the above configuration makes it possible to easily perform maintenance on the developing unit 200 in which the corresponding set Se of the vaporizer 501 and the concentration sensor 550 is arranged adjacent to the rear surface.

### Example 1 of the Treatment Sequence

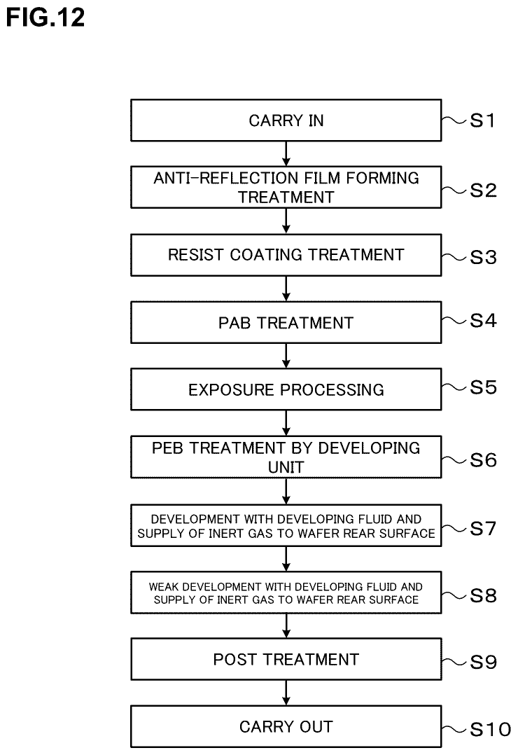

Next, an example of the treatment sequence executed by the wafer treatment system 1 will be explained. FIG. 12 is a flowchart illustrating main processes of Example 1 of the treatment sequence.

### (Step S1)

First, the wafer W is carried into the wafer treatment system 1.

Specifically, the cassette C housing a plurality of wafers W is carried into the cassette station 2 of the wafer treatment system 1 and mounted on the cassette stage plate 24. Then, the wafers W in the cassette C are successively taken out by the wafer carrier apparatus 22 or the wafer carrier apparatus 23, and carried to the delivery apparatus in the third block G3.

### (Step S2)

Next, the anti-reflection film forming treatment is performed on the wafer W to form an anti-reflection film on the wafer W.

Specifically, the wafer W carried to the delivery apparatus in the third block G3 is supported by the wafer carrier apparatus 33 and carried to the anti-reflection film forming apparatus provided in the first block G1, in which an anti-reflection film is formed as a base film for the metal-containing resist in a manner to cover the front surface of the wafer W. This Step S2 may be omitted.

### (Step S3)

Next, the resist coating treatment is performed on the wafer W to form a resist film on the wafer W.

Specifically, the wafer W is supported by the wafer carrier apparatus 33 and carried to the resist film forming apparatus provided in the first block G1, in which a metal-containing resist film is formed in a manner to cover the anti-reflection film as the base film on the wafer W.

### (Step S4)

Subsequently, the wafer W is subjected to a PAB treatment.

Specifically, the wafer W is supported by the wafer carrier apparatus 33, carried to a thermal treatment apparatus for the PAB treatment in the second block G2, and subjected to the PAB treatment. The wafer W is then carried to the delivery apparatus in the fifth block G5. Note that when the plurality of treatment stations 3 are present as in FIGS. 1 and 2, the wafer W is once placed in the delivery apparatus in the fourth block G4 before being carried to the delivery apparatus in the fifth block G5, and then delivered to/from the plurality of wafer carrier apparatuses 33.

### (Step S5)

Next, the wafer W is subjected to exposure processing.

Specifically, the wafer W carried to the delivery apparatus in the fifth block G5 is carried by the wafer carrier apparatus 41 and the wafer carrier apparatus 42 to the exposure apparatus, in which the wafer W is subjected to pattern exposure processing using EUV (Extreme Ultra-Violet) light. The pattern exposure processing is exposure processing of transferring a pattern of a mask. The wafer W subjected to the exposure processing is carried by the wafer carrier apparatus 41 and the wafer carrier apparatus 42 to the delivery apparatus in the fifth block G5.

### (Step S6)

Next, the wafer W is subjected to a PEB treatment by the developing unit 200.

Specifically, for example, the wafer W is first carried into the treatment container 300 of the developing unit 200.

More specifically, the wafer W carried to the delivery apparatus in the fifth block G5 after the exposure processing is carried by the wafer carrier apparatus 33 into the treatment container 300, then the raising and lowering pins 390 are raised, and the wafer W is delivered from the wafer carrier apparatus 33 to the raising and lowering pins 390. Then, the raising and lowering pins 390 are lowered, and the wafer W is placed on the temperature regulation plate 380 at the initial position. Subsequently, the temperature regulation plate 380 is moved to the delivery position above the hot plate 360. Thereafter, the raising and lowering pins 370 are raised, and the wafer W is delivered to the raising and lowering pins 370. Then, the temperature regulation plate 380 is returned to the initial position.

After the wafer W is carried into the treatment container 300, the PEB treatment is performed on the wafer W.

Specifically, for example, the upper chamber 321 is lowered and the inside of the chamber 320 is sealed to form the treatment space K1. Then, the raising and lowering pins 370 are lowered and the wafer W is moved to a PEB treatment height away from the hot plate 360 by a predetermined distance, and the PEB treatment is started. The PEB treatment height is specifically a height where the temperature of the wafer W becomes a predetermined temperature at which dehydration condensation of the metal-containing resist on the wafer W proceeds, and the predetermined temperature is concretely, for example, 140 to 160° C.

During the PEB treatment, at least one of evacuation of the treatment space K1 through the central exhaust path 340 and evacuation of the treatment space K1 through the outer peripheral exhaust path 350 is performed.

Besides, the shower head 330 may be configured to be able to supply gas for the PEB treatment (for example, a temperature and humidity adjusting gas containing oxygen) so that the gas for the PEB treatment may be discharged from the shower head 330 to the treatment space K1 during the PEB treatment.

For example, after a lapse of a predetermined time after the wafer W is moved to the PEB treatment height, the PEB treatment is ended.

Note that the PEB treatment may be performed by the thermal treatment apparatus for the PEB treatment in the second block G2.

### (Step S7)

Subsequently, the wafer W is developed with the developing fluid adjusted in concentration of the weak acid. Specifically, the wafer W is developed as above.

Specifically, for example, the wafer W after the PEB treatment is not carried out of the developing unit 200 and the raising and lowering pins 370 supporting the wafer W are first lowered in the same developing unit 200. This brings the wafer W closer to the hot plate 360, more specifically, the wafer W is delivered from the raising and lowering pins 370 to the hot plate 360 (specifically, the protrusions 360c) and supported thereon. Further, the wafer W is sucked to the hot plate 360 through the suction holes (not illustrated).

Then, the developing fluid adjusted in temperature and concentration of the weak acid from the supply mechanism 500 is supplied to the treatment space K1, and the wafer W is developed with the developing fluid.

Specifically, the developing fluid adjusted in temperature and concentration of the weak acid to desired values is discharged from the shower head 330 toward the front surface side of the wafer W. Further, at least one of the evacuation of the treatment space K1 through the central exhaust path 340 and the evacuation of the treatment space K1 through the outer peripheral exhaust path 350 is performed. Thus, the wafer W heated by the hot plate 360 is exposed to an acid atmosphere containing the gas of the weak acid in the treatment space K1. When the metal-containing resist film on the wafer W is exposed to the acid atmosphere, an unexposed portion reacts with the gas of the weak acid and lowers in molecular weight. Further, the unexposed portion which has lowered in molecular weight by the reaction with the gas of the weak acid of the metal-containing resist film on the wafer W sublimes by the heating of the wafer W, whereby a pattern of the metal-containing resist is formed. For example, in the case where the gas of the weak acid is an acetic acid gas and the metal-containing resist contains tin as metal, tin acetate sublimes. The sublimate is emitted to the outside of the treatment space K1 by evacuating the treatment space K1.

Further, at Step S7, the insert gas is also discharged from the discharge ports 360d of the hot plate 360 toward the rear surface side of the wafer W.

This can suppress the wraparound adhesion of the development-time product to the rear surface of the wafer W at Step S7.

The discharge of the developing fluid from the shower head 330, the evacuation of the treatment space K1, and the discharge of the inert gas from the discharge ports 360d at Step S7 are performed so that the inside of the treatment space K1 is brought to a predetermined pressure equal to or higher than the atmospheric pressure.

Note that the “atmospheric pressure” is, for example, 670 Torr to 760 Torr.

### (Step S8)

Next, a weak development with the developing fluid adjusted in concentration of the weak acid is performed on the wafer W.

Specifically, the weak development with the developing fluid adjusted in temperature and concentration of the weak acid from the supply mechanism 500 is performed on the wafer W.

More specifically, the following is performed subsequent to Step S7.
Discharge of the developing fluid adjusted in temperature and concentration of the weak acid toward the front surface side of wafer W from the shower head 330
At least one of the evacuation of the treatment space K1 through the central exhaust path 340 and the evacuation of the treatment space K1 through the outer peripheral exhaust path 350
The discharge of the inert gas from the discharge ports 360d of the hot plate 360 toward the rear surface side of the wafer W

However, at Step S8, for example, at least one of the following is performed so that the development with the developing fluid is weaker than that at Step S7.
A decrease in discharge amount of the developing fluid from the shower head 330 (namely, a decrease in supply amount of the developing fluid to be supplied from the supply mechanism 500 to the shower head 330)
A decrease in temperature of the developing fluid to be discharged from the shower head 330 (namely, a decrease in temperature of the developing fluid to be supplied from the supply mechanism 500 to the shower head 330)
A decrease in concentration of the weak acid in the developing fluid from the shower head 330 (namely, a decrease in concentration in the developing fluid to be supplied from the supply mechanism 500 to the shower head 330)
Addition of a weakly developing substance to the mixed solution of the weak acid and the organic solvent to be supplied to the vaporizer

The concentration of the weak acid in the developing fluid can be regulated, for example, by the heating temperature of the mixed fluid in the flow path 543 in the vaporizer 501 or the supply flow rate of the inert gas to the vaporizer 501 as explained above.

The weakly developing substance is a substance having a value of an acid dissociation constant (pka) larger than that of the weak acid contained in the original mixed solution. When the weak acid contained in the original mixed solution is acetic acid (pka≈4.76), carboxylic acid-based, alcohol-based, and aminosilane-based substances as the weakly developing substance are as follows.
Carboxylic acid-based
   Propionic acid (pka≈4.87)
Alcohol-based
   Methanol (pka≈15.4), 2,2,2-Trifluoroethanol (pka≈12.4), Nonafluoro-tert-butyl alcohol (pka≈5.4), phenol (pka≈9.95), pentafluorophenol (pka≈5.5)
Aminosilane-based
   Trimethylsilyl dimethylamine (TMSDMA) (pka≈10.7)

Further, the weakly developing substance to be added is preferably a substance having volatility to become gas at room temperature.

Further, at Step S8, the inert gas is also discharged from the discharge ports 360d of the hot plate 360 toward the rear surface side of the wafer W as at Step S7.

This can suppress the wraparound adhesion of the development-time product to the rear surface of the wafer W at Step S8.

Further, also at Step S8, the discharge of the developing fluid from the shower head 330, the evacuation of the treatment space K1, and the discharge of the inert gas from the discharge ports 360d are performed so that the inside the treatment space K1 is at a predetermined pressure equal to or higher than the atmospheric pressure, as at Step S7.

After a lapse of a predetermined time from the start of Step S8, the supply of the developing fluid to the treatment space K1 is stopped, specifically, the opening/closing valve 504 installed in the supply path 502 is brought into a closed state, with which Step S8 is ended.

The temperature of the wafer W at the development at Step S7 and Step S8 is higher than the temperature at the PEB treatment at Step S6 and is, for example, 180 to 200° C. However, the temperature of the hot plate 360 does not need to be changed between the development and the PEB treatment. This is because the wafer W is brought closer to the hot plate 360 at the development at Step S7 and Step S8 than at the PEB, more specifically, supported by the hot plate 360 (specifically, the protrusions 360c). In other words, in the treatment sequence in this example, the wafer W is brought closer to the hot plate 360 at the developing treatment than at the PEB treatment, so that the treatment temperature of the wafer W at the developing treatment is made higher than that at the PEB treatment.

The evacuation of the treatment space K1 and the discharge of the inert gas from the discharge ports 360d may be continued even after the stop of the supply of the developing fluid to the treatment space K1 to replace the atmosphere containing the gas of the weak acid in the treatment space K1 with the atmosphere of the inert gas. In the case where the replacement is performed, the evacuation of the treatment space K1 and the discharge of the inert gas from the discharge ports 360d are continued, for example, until a lapse of a predetermined time after the stop of the supply of the developing fluid to the treatment space K1. Further, in the case when the replacement is not performed, the evacuation of the treatment space K1 and so on are also stopped together with the supply of the developing fluid to the treatment space K1.

Thereafter, the wafer W is carried out of the treatment container 300.

Specifically, the wafer W is carried out of the treatment container 300 and carried to the outside of the developing unit 200, for example, by a procedure reverse to that at the time of carrying into the treatment container 300 at Step S6.

### (Step S9)

After the development, a POST treatment is performed on the wafer W.

Specifically, the wafer W is carried by the wafer carrier apparatus 33 to a thermal treatment unit 40 for the POST treatment, and subjected to the POST treatment. This Step S9 may be omitted.

### (Step S10)

Then, the wafer W is carried out of the wafer treatment system 1.

Specifically, the wafer W is carried by the wafer carrier apparatus 33 to the delivery apparatus in the third block G3, and carried by the wafer carrier apparatus 22 or 23 in the cassette station 2 to the cassette C on the predetermined cassette stage plate 24. Thus, a series of photolithography processes is completed.

### Main Operations and Effects of this Embodiment

As explained above, Example 1 of the treatment sequence includes a process (Step S7 and Step S8) of developing the wafer W on which the coating film of the resist (specifically, the metal-containing resist) has been formed and which has been subjected to the exposure processing. Further, the developing process (Step S7 and Step S8) supplies the developing fluid containing the gas of the weak acid into the treatment space K1 to develop the wafer W in the treatment space K1. Then, the concentration of the weak acid of the developing fluid supplied into the treatment space K1 is adjusted, specifically, adjusted to have a desired value. Therefore, according to Example 1 of the treatment sequence, it is possible to develop the wafer W with a desired strength as compared with the case where the concentration of the weak acid of the developing fluid supplied into the treatment space K1 is not adjusted. Accordingly, it is possible to suppress excessive development or insufficient development on the wafer W, and therefore to satisfactorily perform the development using the developing fluid containing the gas of the weak acid.

Besides, in Example 1 of the treatment sequence, the strength of the development on the wafer W with the developing fluid is made weaker at Step S8 that is the latter stage of the developing process (Step S7 and Step S8) than that at Step S7. In the development of the wafer W with the developing fluid containing the gas of the weak acid, the removal of the coating film proceeds in a thickness direction of the coating film of the resist, namely, the longitudinal direction, and then the removal of the coating film proceeds in a direction parallel with the surface of the wafer W, namely, the lateral direction. Further, in the coating film of the resist, the exposed amount in the exposure processing by the exposure apparatus is lower at the lower portion side than the front surface side. Therefore, in the negative development of the coating film of the resist, the removal of the coating film is likely to proceed more on the lower portion side than on the front surface side. For example, in the coating film of the metal-containing resist, the substitution of the ligand for a hydroxyl group and the dehydration condensation thereafter proceed less on the lower portion side than on the front side, so that the removal of the coating film is more likely to proceed in the negative development. Accordingly, if the development is strong at the latter stage of the development that is a stage where the removal of the coating film proceeds in the lateral direction, a pattern of the resist obtained by the development becomes a shape thin at a lower portion in a cross-sectional view. Hence, by making the strength of the development on the wafer W with the developing fluid weaker at Step S8 that is the latter stage of the developing process than that at Step S7 as above, it is possible to suppress thinning of the pattern of the resist obtained by the development at the lower portion.

Further, in Example 1 of the treatment sequence, both the PEB treatment and the developing treatment are performed by the developing unit 200 and, at that time, both the treatments are continuously performed without taking the wafer W out of (the treatment container 300 of) the developing unit 200. Accordingly, it is possible to suppress variation between wafers W in the time from the end of the PEB treatment to the start of the developing treatment.

Further, in the above example, in the case of continuously performing the PEB treatment and the developing treatment including the heating of the wafer W in the same developing unit 200, the wafer W is brought closer to the hot plate 360 at the developing treatment than at the PEB treatment to thereby make the treatment temperature for the wafer W at the developing treatment higher than at the PEB treatment. Therefore, it is possible to make the treatment temperature of the wafer W at the developing treatment higher than at the PEB treatment while keeping the set temperature of the hot plate 360 constant. Accordingly, it is unnecessary to change the set temperature of the hot plate for the developing treatment after the PEB treatment, and it is unnecessary to wait until the temperature of the hot plate becomes constant after the change of the set temperature. Therefore, according to this example, even in the case of successively performing the PEB treatment and the developing treatment including the heating of the wafer W by the same developing unit, the throughput can be improved in the case where the treatment temperature of the wafer W at the developing treatment is higher than that at the PEB treatment.

The developing apparatus according to this embodiment includes: the vaporizer 501 as a developing fluid generator which generates the developing fluid containing the gas of the weak acid from a developing liquid; and the developing unit 200 which has the chamber 320 forming the treatment space K1 for housing the wafer W and provided with the discharge ports 331 for discharging the developing fluid to the treatment space K1, and develops the wafer W with the developing fluid. Further, in the developing apparatus according to this embodiment, the developing unit 200 discharges the developing fluid from the discharge ports 331 toward the front surface side of the wafer W in the treatment space K1, and has other discharge ports 360d for discharging the predetermined gas (specifically, the inert gas) toward the rear surface side of the wafer W in the treatment space K1. Therefore, in the developing unit 200, the predetermined gas (specifically, the inert gas) can be discharged toward the rear surface side of the wafer W in the treatment space K1 at the development, and thereby suppress the wraparound adhesion of the development-time product to the rear surface of the wafer W. Accordingly, it is possible to satisfactorily perform the development using the developing fluid containing the gas of the weak acid.

Further, in this embodiment, the heat exchanger 364 as the heating part which heats the predetermined gas (specifically, the inert gas) to be discharged toward the rear surface side of the wafer W in the treatment space K1 is provided in the developing unit 200. Therefore, it is possible to suppress cooling of the wafer by the predetermined gas sprayed to the wafer W at the development. Specifically, it is possible to suppress cooling of the wafer W, which is heated at the development, by the predetermined gas at the development.

Further, in this embodiment, the developing unit 200 further has the hot plate 360 which supports the wafer W in the treatment space K1, the groove 360e in the ring shape in plan view is formed at the upper surface of the hot plate 360, specifically, the groove 360e in the circular ring shape in plan view is formed at the upper surface of the main body part 360a of the hot plate 360. The discharge ports 360d are formed at the bottom portion of the groove 360e along the groove 360e. Accordingly, it is possible to suppress circumferential bias of the purge gas discharged from the discharge ports 360d.

The supply mechanism 500 as the developing fluid supply apparatus according to this embodiment has the supply path 502 connected to the developing unit 200, the vaporizer 501 as the developing fluid generator, and the heater 503 as the heating part which heats the developing fluid to be supplied to the developing unit 200 through the supply path 502. In order to allow the development of the metal-containing resist of the wafer W using the developing fluid containing the gas of the weak acid to appropriately proceed, the temperature at the time when the developing fluid reaches the wafer W in the developing unit 200 is preferably higher than room temperature, specifically, preferably almost the same as the temperature of the wafer W to be heated. The supply mechanism 500 has the heater 503 and thereby can bring the temperature of the developing fluid at the time of reaching the wafer W to the above temperature. In other words, by the supply mechanism 500 according to this embodiment, it is possible to supply the developing fluid containing the gas of the weak acid suitable for the development of the metal-containing resist.

Besides, as explained above, the set Se of the vaporizer 501 and the concentration sensor 550 may be configured to be provided at the same height as the developing unit 200 at the supply destination of the developing fluid. This can shorten the distance of the supply path 502 from the vaporizer 501 to the developing unit 200. As a result, it is possible to easily manage the temperature of the supply path 502 where dew condensation of the developing fluid occurs at a low temperature. Further, it is possible to shorten the time from when the concentration of the weak acid in the developing fluid generated in the vaporizer 501 is changed until when the concentration of the weak acid in the developing fluid to be actually supplied to the developing unit 200 is changed, namely, to increase the control responsiveness of the concentration of the weak acid in the developing fluid.

### Example 2 of the Treatment Sequence

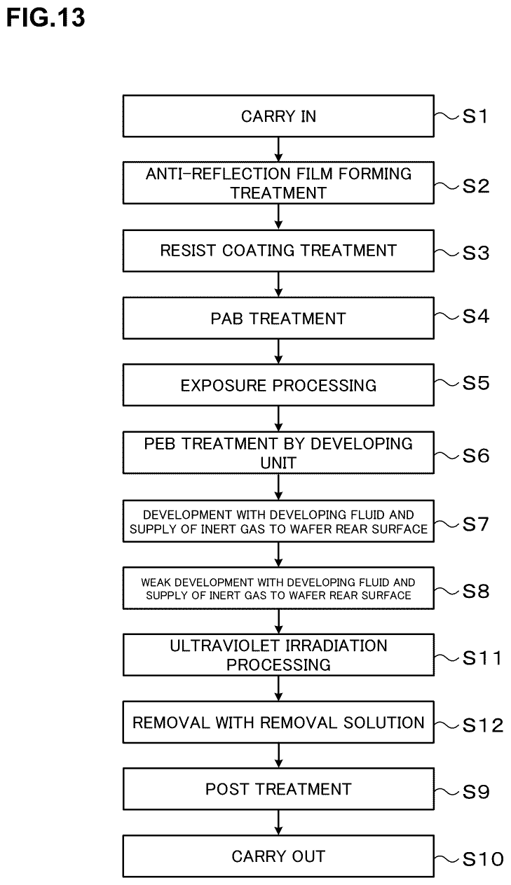

FIG. 13 is a flowchart illustrating main processes of Example 2 of the treatment sequence executed by the wafer treatment system 1.

In this example, unlike Example 1 of the treatment sequence, after the process of development with the developing fluid, namely, after Step S8, ultraviolet irradiation processing is performed on the wafer W to modify a residue after the development on the wafer W (Step S11). Then, the modified residue is removed with a removal solution (Step S12).

At Step S11, specifically, the wafer W after the development is supported by the wafer carrier apparatus 33 and carried to the ultraviolet irradiation apparatus in the treatment station 3 and subjected to the ultraviolet irradiation processing. The ultraviolet irradiation apparatus is provided in the second block G2 in the treatment station 3 similar to, for example, the thermal treatment apparatus. The ultraviolet irradiation processing is processing of irradiating the entire upper surface, namely, the entire surface of the wafer W with an ultraviolet ray. Specifically, the ultraviolet irradiation processing is processing of irradiating the entire surface of the wafer W with an ultraviolet ray without a mask. Note that the “entire surface of the wafer W” includes at least the entire device formation region of the wafer W. The wavelength of the ultraviolet ray to be used for the ultraviolet irradiation processing is longer than that of an EUV light and is, for example, 100 nm or more and less than 300 nm. Further, the ultraviolet irradiation processing is performed, for example, in an atmospheric gas atmosphere.

The ultraviolet irradiation processing modifies the unexposed portion of the metal-containing resist on the wafer W remaining after the development. Specifically, after the bond between the metal and the ligand in the remaining metal-containing resist is cut (namely, the ligand is released) by the ultraviolet irradiation at the unexposed portion of the metal-containing resist on the wafer W, the resist is hydrated, namely, hydrophilized. Note that the exposed portion of the metal-containing resist on the wafer W is hydrophobized due to the occurrence of the dehydration condensation, and the above hydrophilization hardly occurs in the exposed portion by the ultraviolet irradiation.

At Step S12, specifically, the wafer W after the ultraviolet irradiation is supported by the wafer carrier apparatus 33 and carried to the removing apparatus in the treatment station 3 in which the modified residue on the wafer W is removed with the removal solution. The removing apparatus is provided in the first block G1 in the treatment station 3 similar to, for example, the resist film forming apparatus. As the removal solution, a polar solution is used, specifically, for example, a water-based chemical solution is used, and more specifically, for example, an aqueous solution of tetramethylammonium hydroxide (TMAH) is used. Most or all of the residue of the metal-containing resist on the wafer W which has been hydrophilized by the irradiation with the ultraviolet ray is the one present at the unexposed portion and is dissolved in the polar solution and removed from the top of the wafer W. Note that the exposed portion of the metal-containing resist on the wafer W is still low in polarity because the hydrophilization hardly occurs in the exposed portion as explained above, and does not dissolve in the polar solution and is not removed from the top of the wafer W. In consideration of the case where the ultraviolet irradiation has been performed before the development, it may be necessary to examine a means for adjusting the degree of hydrophilization in a pattern boundary close region such as an intermediate exposure region in the metal-containing resist, in order to stabilize the pattern roughness. In other words, by performing the ultraviolet irradiation processing after the pattern is formed by the development, it becomes possible to modify the residue while suppressing a risk of deteriorating the pattern roughness.

Example 2 of the treatment sequence further includes, after the developing process, a process of performing the ultraviolet irradiation processing on the wafer W to modify the residue after the development on the wafer W (Step S11) and a process of then removing the modified residue with the removal solution (Step S12). According to this example of the treatment sequence, it is possible to reduce the residue after the development on the wafer W and therefore to perform better development, specifically, obtain a better pattern of the resist.

Note that Step S11 and Step S12 are performed, for example, between Step S8 and Step S9.

### Example 3 of the Treatment Sequence

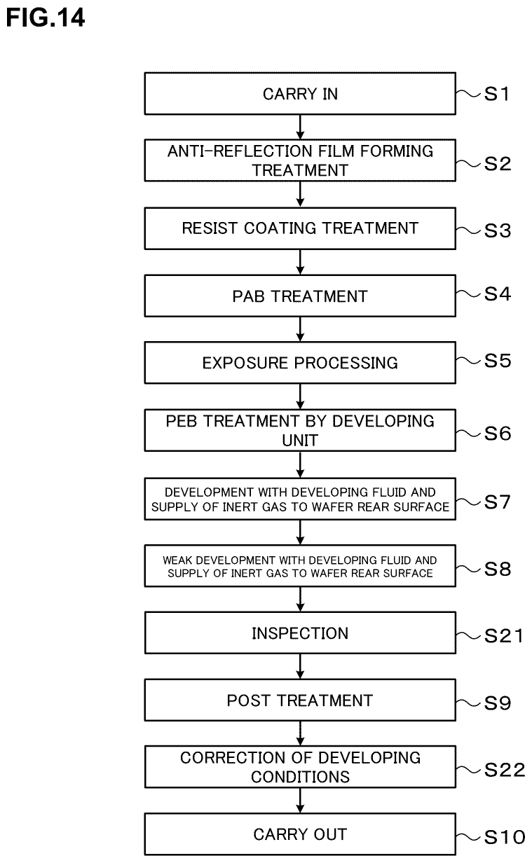

FIG. 14 is a flowchart illustrating main processes of Example 3 of the treatment sequence executed by the wafer treatment system 1.

In this example, unlike Example 1 of the treatment sequence, after the process of developing with the developing fluid, namely, after Step S8, inspection of the wafer W is performed (Step S21), and then treatment conditions at the developing process, namely, the treatment conditions at Step S7 and Step S8 are corrected based on its inspection results by the controller 100 as a corrector (Step S22).

At Step S21, specifically, the wafer W after the development is carried by the wafer carrier apparatus 33 or the like into the inspection apparatus in the wafer treatment system 1 and inspected. Specifically, for example, the entire upper surface of the wafer W is imaged by the inspection apparatus, and an image of the wafer W based on an imaging result is acquired by the controller 100.

At Step S22, specifically, for example, the treatment conditions at Step S7 and Step S8 on the wafer W thereafter are corrected by the controller 100 based on the image of the wafer W as the inspection result at Step S21. The correction is performed, for example, such that the development result with the developing fluid becomes more uniform within the plane of the wafer W.

The treatment conditions to be corrected are conditions influencing the critical dimension (CD) of the pattern of the metal-containing resist obtained by the development and, for example, the heating value of the heater 360b in each of the regions R₁ to R₅ of the hot plate 360. If there is a portion where the critical dimension of the pattern of the metal-containing resist is small within the wafer W after the development, the correction is made so that the heating value of the heater 360b in any of the regions R₁ to R₅ of the hot plate 360 corresponding to that portion becomes small. By performing the adjustment of the heating value in any of the regions R₁ to R₅ of the hot plate 360, the strength for the removing action of the resist film with the developing fluid changes in the corresponding region in the pattern of the metal-containing resist to control the critical dimension of the pattern. The reaction process leading to an insoluble state with respect to the developing fluid through the condensation reaction of the metal-containing resist is different from that of the conventional chemically amplified resist. The reaction at the PEB is significantly influenced by moisture around the film of the metal-containing resist, whereas the pattern critical dimension does not sensitively change with respect to the temperature change itself at the PEB. Therefore, the pattern critical dimension adjustment is difficult by the control of the temperature or the temperature distribution at the PEB with respect to the film of the metal-containing resist.

From the above, to adjust the pattern critical dimension of the metal-containing resist, the method of adjusting the removing action of the developing fluid on the unexposed portion of the metal-containing resist film by adjusting the temperature condition at the development is preferable to that by controlling the temperature at the PEB because the pattern critical dimension easily changes and is easily adjusted to a desired pattern critical dimension.

Further, the treatment condition to be corrected may be the temperature of the inert gas discharged from the discharge ports 360d.

Further, the treatment condition to be corrected may be the distribution of the concentration of the developing fluid in the treatment space K1, and specifically, may be the ratio (balance) between the exhaust rate from the treatment space K1 through the central exhaust path 340 and the exhaust rate from the treatment space K1 through the outer peripheral exhaust path 350, which influences the distribution of the concentration. According to the repeated examinations by the present inventors, if the exhaust rate from the treatment space K1 through the central exhaust path 340 is larger, the concentration of the developing fluid in the treatment space K1 becomes high above the central portion of the wafer W and the development with the developing fluid is more likely to proceed at the central portion of the wafer W. On the other hand, if the exhaust rate from the treatment space K1 through the outer peripheral exhaust path 350 is larger, the concentration of the developing fluid in the treatment space K1 becomes high above the peripheral portion of the wafer W and the development with the developing fluid is more likely to proceed at the peripheral portion of the wafer W. Accordingly, when the critical dimension of the pattern of the metal-containing resist at the peripheral portion of the wafer W after the development is large, the correction of the balance is performed so that the exhaust rate from the treatment space K1 through the outer peripheral exhaust path 350 becomes larger.

According to Example 3 of the treatment sequence, the shape of the pattern of the resist after the development can be made closer to a desired one. Specifically, according to Example 3 of the treatment sequence, the shape of the pattern of the metal-containing resist obtained by the development can be made uniform within the plane of the wafer.

Note that Step S21 is performed, for example, between Step S8 and Step S9, and Step S22 is performed, for example, after Step S21 and before Step S1 for the next wafer W.

### Modification Example of Example 3 of the Treatment Sequence

In the above example, the correction of the treatment conditions in the process of developing with the developing fluid is performed based on the inspection result of the wafer W after the developing process, namely, after the development by the developing unit 200. Instead of this, the correction of the treatment conditions in the process of developing with the developing fluid may be performed based on any of the following.
The state of the wafer W (for example, the temperature distribution of the wafer W) at the development (specifically, at Step S7 and Step S8, namely, at the development by the developing unit 200)
The state of the developing unit 200 at the development (for example, the output of the heater 360b for each of the regions R₁ to R₅ of the hot plate 360)
The inspection result of the wafer after the post-process performed on the wafer W after the development (for example, etching using the resist pattern after the development as a mask)
The state of the wafer W at the post-process (for example, the temperature distribution of the wafer W)
The state of a post-process treatment part at the post-process (for example, the temperature distribution of the heating part which supports and heats the wafer at the etching in an etching apparatus which performs etching using the resist pattern after the development as the mask)

Note that when using the temperature distribution of the wafer W as the state of the wafer W at the development, for example, the temperature of the wafer W at the development is acquired by temperature sensors provided at the raising and lowering pins 370 or the protrusions 360c of the hot plate 360.

For example, when the temperature distribution of the wafer W where the peripheral portion of the wafer W becomes low in temperature due to the discharge of the inert gas from the discharge ports 360d is acquired, the balance of the above exhaust rates is corrected so that the exhaust rate from the treatment space K1 through the outer peripheral exhaust path 350 becomes larger.

Further, if the measurement results of the temperatures of the wafer W by the temperature sensors provided at the raising and lowering pins 370 and the measurement results of the temperatures of the wafer W by the temperature sensors provided at the protrusions 360c located outside the raising and lowering pins 370 are different, the correction (adjustment) of developing treatment conditions may be performed so as to compensate for the difference in the measurement results. In this case, the developing treatment conditions to be corrected are the above balance between the exhaust rates, the temperature of the inert gas discharged from the discharge ports 360d, and so on.

### Example 4 of the Treatment Sequence

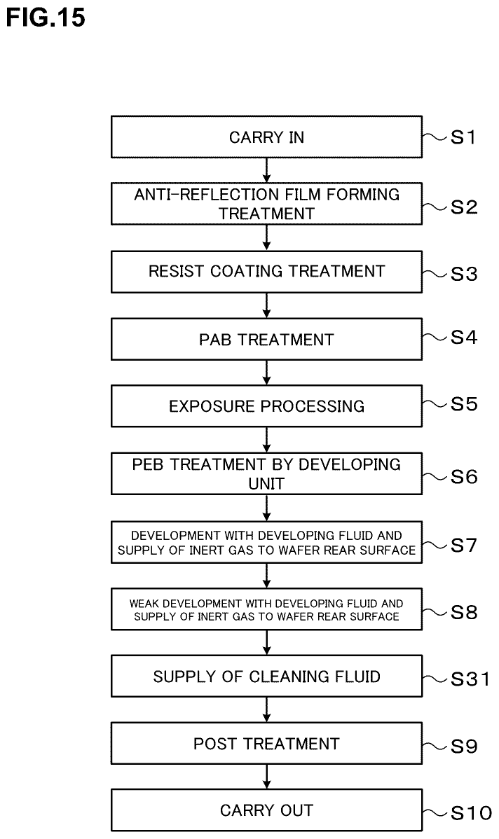

FIG. 15 is a flowchart illustrating main processes of Example 4 of the treatment sequence executed by the wafer treatment system 1.

In this example, unlike Example 1 of the treatment sequence, after the process of developing with the developing fluid, namely, after Step S8, the above developing fluid is supplied as a cleaning fluid containing gas of a weak acid into the treatment space K1 with the wafer W not located in the treatment space K1 (Step S31)

At Step S31, specifically, for example, at Step S8, the wafer W after the development is carried out of the treatment container 300, then the upper chamber 321 is lowered, and the inside of the chamber 320 is sealed to form again the treatment space K1. Thereafter, the developing fluid as the cleaning fluid adjusted in temperature and concentration of the weak acid to desired values is discharged from the shower head 330 toward the front surface side of the hot plate 360. Further, at least one of the evacuation of the treatment space K1 through the central exhaust path 340 and the evacuation of the treatment space K1 through the outer peripheral exhaust path 350 is performed. Thus, the components (for example, the hot plate 360 and the chamber 320) of the developing unit 200 exposed to the treatment space K1 are exposed to the acid atmosphere containing the gas of the weak acid. Then, the development-time product adhering to the components reacts with the gas of the weak acid and lowers in molecular weight, and then vaporizes by heat or the like. The vaporized substance is emitted to the outside of the treatment space K1 by the evacuation of the treatment space K1.

According to Example 4 of the treatment sequence, the development can suppress the deterioration in cleanliness of the chamber 320 and so on.

Note that Step S31 may be performed for each wafer W or may be performed every time when a predetermined number equal to or more than two wafers W are treated. Further, Step S31 may be performed in parallel with another step such as Step S9 where the POST treatment is performed.

Further, at Step S31, the developing fluid to be supplied as the cleaning fluid may be supplied such that the ability to remove the resist (specifically, the metal-containing resist) is higher than that of the developing fluid supplied at the development at Step S7 and Step S8. Specifically, at least one of the following may be satisfied.
The developing fluid as the cleaning fluid is higher in supply flow rate.
The developing fluid as the cleaning fluid is higher in temperature.
The developing fluid as the cleaning fluid is higher in concentration of the weak acid.
The developing fluid as the cleaning fluid is smaller in acid dissociation constant (pka) of the weak acid.
The weakly developing substance is added to the mixed solution containing the weak acid to be vaporized in the supply mechanism 500 only in the developing fluid at the development.

Thus, the removal, namely, cleaning of the development-time product from the components of the developing unit 200 exposed to the treatment space K1 can be performed in a short time.

In the case where the developing fluid as the cleaning fluid is smaller in acid dissociation constant (pka) of the weak acid or the like, namely, in the case where the types of the gases of the weak acids contained in the developing fluids are different or the like, the supply mechanism for the developing fluid as the cleaning fluid and the supply mechanism for the developing fluid for the development may be separately provided.

### Other Example 1 of the Supply Mechanism for the Developing Fluid

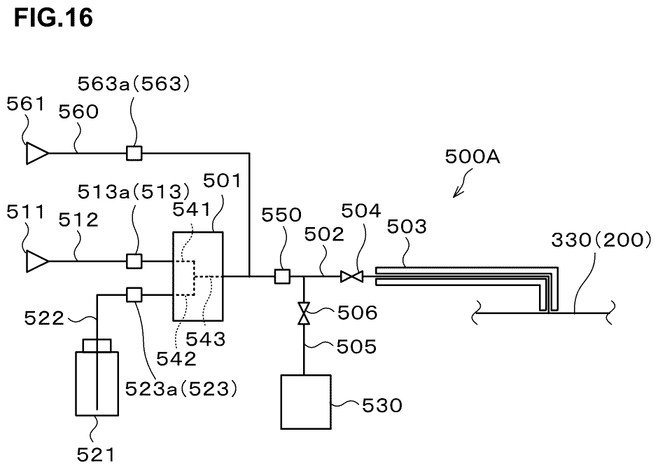

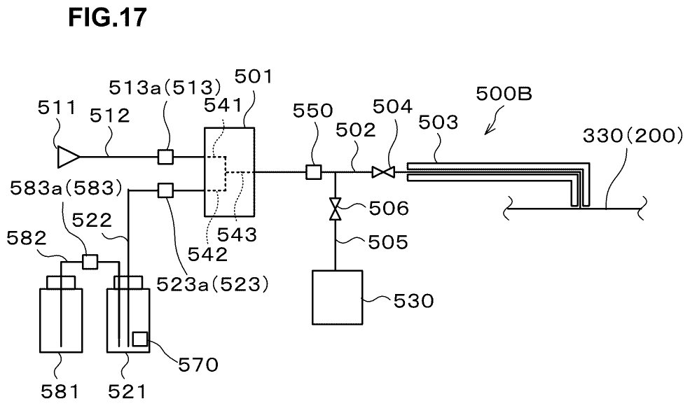

FIG. 16 is a diagram for explaining Other example 1 of the supply mechanism for the developing fluid.

A supply mechanism 500A for the developing fluid in FIG. 16 has a dilution path 560 in addition to the concentration sensor 550 and so on. The dilution path 560 is connected to the supply path 502 and supplies an inert gas as a dilution gas for diluting the developing fluid to be supplied to the developing unit 200 through the supply path 502, to the supply path 502.

The dilution path 560 has one end connected to the supply path 502 and another end connected to a supply source 561 of the inert gas as the dilution gas. Further, the dilution path 560 is provided with a supply equipment group 563 including an opening/closing valve for controlling the distribution of the inert gas in the dilution path 560, a gas flow rate regulating valve 563a for regulating the flow rate of the inert gas, and so on. The supply equipment group 563 is controlled by the controller 100.

In the supply mechanism 500A, the flow rate of the inert gas to be supplied from the dilution path 560 to the supply path 502 is adjusted by the control of the controller 100 based on the measurement result by the concentration sensor 550. For example, if the concentration of the weak acid in the mixed solution in the tank 521 is high and the concentration of the weak acid in the developing fluid generated by vaporization in the vaporizer 501, namely, the concentration of the weak acid measured by the concentration sensor 550 is high, the flow rate of the inert gas to be supplied from the dilution path 560 to the supply path 502 is decreased. On the other hand, if the concentration of the weak acid in the mixed solution in the tank 521 decreases over time and the concentration of the weak acid in the developing fluid generated by vaporization in the vaporizer 501, namely, the concentration of the weak acid measured by the concentration sensor 550 becomes low, the flow rate of the inert gas to be supplied from the dilution path 560 to the supply path 502 is increased.

This can make the concentration of the weak acid in the developing fluid to be supplied to the developing unit 200 through the supply path 502 constant irrespective of the concentration of the weak acid in the mixed solution in the tank 521.

### Other Example 2 of the Supply Mechanism for the Developing Fluid

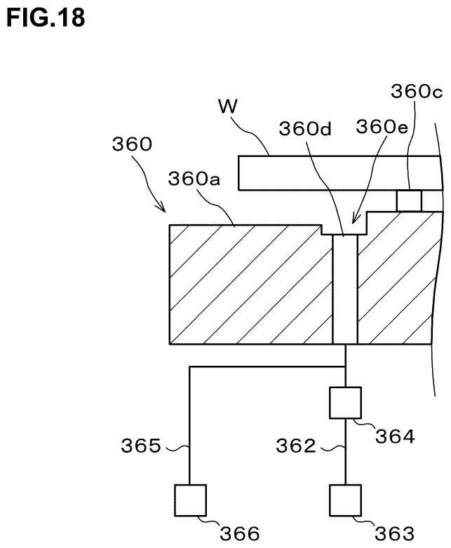

FIG. 18 is a diagram for explaining Other example 2 of the supply mechanism for the developing fluid.

In a supply mechanism 500B for the developing fluid in FIG. 18, a concentration sensor 570 for detecting the concentration of the weak acid in the mixed solution is provided for the tank 521 for storing the mixed solution of the weak acid and the organic solvent.

Further, in the supply mechanism 500B, a tank 581 is connected to the tank 521 through a supply path 582. A chemical solution stored in the tank 581 is higher in concentration of the weak acid than the initial value of the concentration of the weak acid in the mixed solution in the tank 521. For example, when the mixed solution stored in the tank 521 is a chemical solution having an acetic acid concentration of 40%, the chemical solution stored in the tank 581 is a chemical solution having an acetic acid concentration of 100%.

The supply path 582 has one end connected to the tank 521 and another end connected to the tank 581. Further, the supply path 582 is provided with a supply equipment group 583 including an opening/closing valve for controlling the distribution of the chemical solution in the supply path 582, a liquid flow rate regulating valve 583a for regulating the flow rate of the chemical solution, and so on. The supply equipment group 583 is controlled by the controller 100.

In the supply mechanism 500B, even if the concentration of the weak acid in the mixed solution in the tank 521 decreases over time, the chemical solution high in concentration is replenished from the tank 581 to the tank 521 so that the concentration falls within a predetermined range, by the control of the controller 100 based on the measurement result by the concentration sensor 570.

This can make the concentration of the weak acid in the mixed solution in the tank 521 almost constant, so that the concentration of the weak acid in the developing fluid to be supplied to the developing unit 200 through the supply path 502 can be adjusted to be almost constant.

### Another Example of the Method of Changing the Temperature of the Wafer W Between the PEB Treatment and the Development

Unlike the above example, the heat exchanger 364 may be controlled so that the predetermined gas (inert gas) is discharged from the discharge ports 360d not only at the development at Step S7 and Step S8 but also at the PEB treatment at Step S6, and the temperature of the inert gas discharged at the PEB treatment is lower than that at the development. Further, this may lower the temperature of the wafer W at the PEB treatment than at the development.

### Another Example of the Method of Discharging Gas at a Low Temperature from the Discharge Port 360d

FIG. 18 is a view for explaining another example of the method of discharging gas at a low temperature from the discharge port 360d, and is a partially enlarged sectional view schematically illustrating the outline of a configuration of a peripheral portion of the hot plate 360.

In the example of FIG. 18, in addition to the supply path 362 as a high-temperature supply path for supplying a predetermined gas (inert gas) heated by the heat exchanger 364 to the discharge port 360d, a low-temperature supply path 365 is connected to the discharge port 360d.

The low-temperature supply path 365 is provided separately from the supply path 362 and supplies a predetermined gas (inert gas) lower in temperature than the predetermined gas (inert gas) supplied from the supply path 362, to the discharge port 360d. Specifically, the low-temperature supply path 365 is provided, for example, separately from the supply path 362 and supplies the predetermined gas (inert gas) not heated by the heat exchanger 364, to the discharge port 360d. Through the low-temperature supply path 365, the discharge port 360d and a supply mechanism 366 for the inert gas are connected. The supply mechanism 366 has, for example, a supply source of the inert gas and a supply equipment group including an opening/closing valve for controlling the distribution of the inert gas and a gas flow rate regulating valve, which are not illustrated.

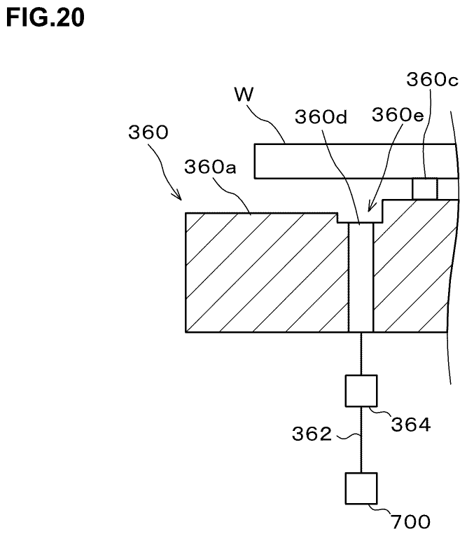

In the case of the configuration in FIG. 20, low-temperature gas supplied through the low-temperature supply path 365 is discharged from the discharge ports 360d at the PEB treatment at Step S6, and high-temperature gas supplied through the supply path 362 as the high-temperature supply path is discharged from the discharge ports 360d at the development at Step S7 and Step S8. This can make the temperature of the wafer W at the PEB treatment lower than at the development.

With this configuration, the temperature of the predetermined gas (inert gas) discharged from the discharge ports 360d can be quickly made higher. Therefore, the temperature of the wafer W can be quickly increased from the temperature suitable for the PEB treatment to the temperature suitable for the development.

Note that a joint portion of the supply path 362 and the low-temperature supply path 365 is preferably located near the discharge ports 360d, for example, located directly below the hot plate 360. Thus, it is possible to more quickly make the predetermined gas (inert gas) discharged from the discharge ports 360d higher.

### Another Example of the Method of Weakening the Development with the Developing Fluid at the Development

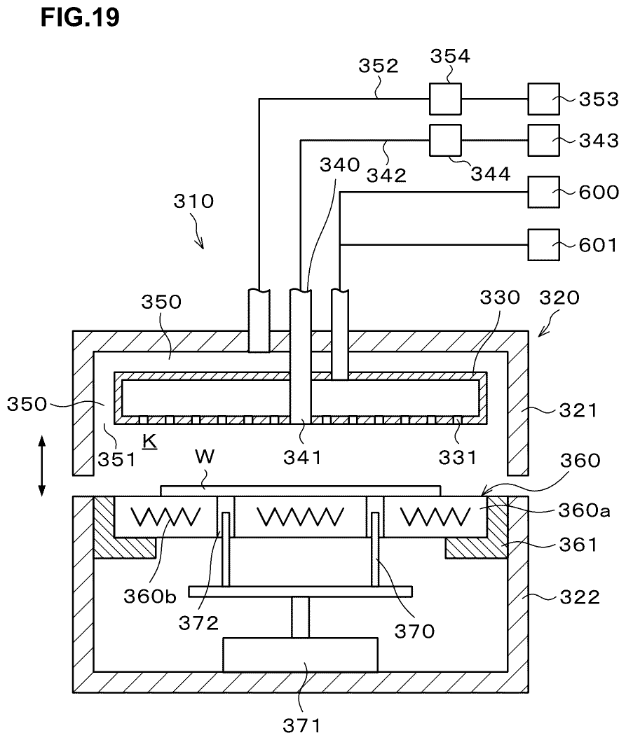

FIG. 19 is a view for explaining another example of weakening the development with the developing fluid at the development.

In this example, to the shower head 330 of the developing unit 200, a plurality of supply mechanisms each including the developing fluid generator are connected. In the example of FIG. 19, two supply mechanisms 600, 601 are connected to the shower head 330 of the developing unit 200. Each of the supply mechanisms 600, 601 is configured, for example, similarly to the above supply mechanism 500.

Further, in this example, the two supply mechanisms 600, 601 supply the developing fluids to the developing unit 200 such that the strengths of the developments with the developing fluids to be supplied are different from each other. Specifically, the supply mechanism 600 for relatively strong development with the developing fluid and the supply mechanism 601 for relatively weak development with the developing fluid satisfy at least one of the following.
The supply flow rate of the developing fluid from the supply mechanism 601 is smaller.
The temperature of the developing fluid supplied from the supply mechanism 601 is lower.
The concentration of the weak acid in the developing fluid supplied from the supply mechanism 601 is lower.
The weakly developing substance is not added to the mixed solution containing the weak acid to be vaporized in the supply mechanism 600, and the weakly developing substance is added to the mixed solution in the supply mechanism 601.

Then, the developing fluid is supplied from the supply mechanism 600 for the relatively strong development with the developing fluid to the developing unit 200 at Step S7 above, and the developing fluid is supplied from the supply mechanism 601 for the relatively weak development with the developing fluid to the developing unit 200 at Step S8 above. In other words, when shifting from Step S7 to Step S8, the supply source of the developing fluid to the developing unit 200 is switched from the supply mechanism 600 to the supply mechanism 601.

According to this method, the change of the development with the developing fluid to a desired strength can be more quickly performed.

### Another Example of Gas Discharged from the Discharge Port 360d Toward the Rear Surface Peripheral Portion of the Wafer W

FIG. 20 is a view for explaining an example of gas discharged from the discharge port 360d, and is a partially enlarged sectional view schematically illustrating the outline of a configuration of a peripheral portion of the hot plate 360.

In the example in FIG. 20, a supply mechanism 700 for a cleaning fluid containing gas of a weak acid as with the developing fluid is connected to the discharge port 360d of the hot plate 360. Therefore, the cleaning fluid is discharged from the discharge port 360d.

The supply mechanism 700 is configured similarly to, for example, the supply mechanism 500, and different from the supply mechanism 500 only in that the connection destination of the supply path 502 is not the shower head 330 but the discharge port 360d and that not the developing fluid but the cleaning fluid is generated and supplied. Note that the supply mechanism 700 connected to the discharge port 360d and the supply mechanism 500 connected to the shower head 330 may share a part of the vaporizer 501 and so on.

In the case of the configuration in FIG. 20, discharge of the cleaning fluid may be performed from the discharge ports 360d in addition to or instead of the discharge of the developing fluid as the cleaning fluid from the shower head 330 at Step S31 in Example 4 of the treatment sequence. Further, the discharge of the developing fluid as the cleaning fluid from the shower head 330 and the discharge of the cleaning fluid from the discharge ports 360d may be alternately performed. In this event, the discharge of the cleaning fluid from the discharge ports 360d may be performed first. Further, when they are alternately performed, for example, the dirt at an upper fine structure portion of the chamber 320 is blown away by the discharge of the cleaning fluid from the discharge ports 360d. On the other hand, the periphery of the shower head 330 and the inner wall of the chamber 320 are cleaned by the discharge of the developing fluid as the cleaning fluid from the shower head 330.

### Example of the Treatment Sequence in the Case of Discharging the Cleaning Fluid from the Discharge Ports 360d

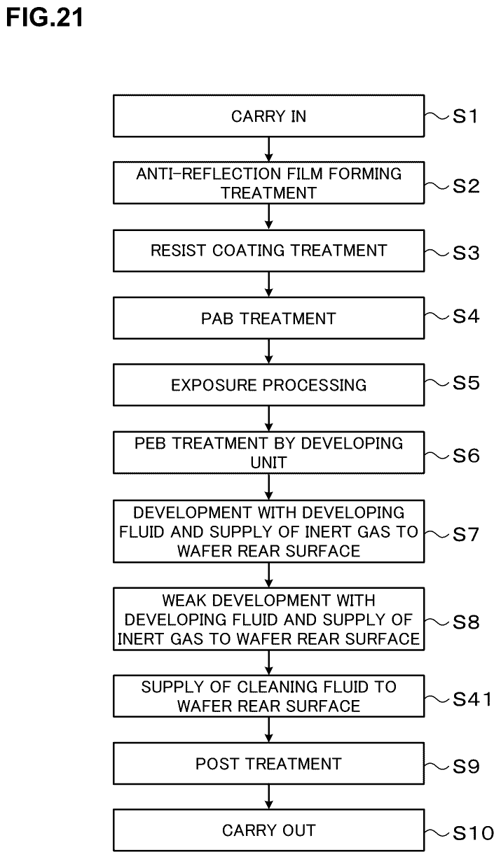

FIG. 21 is a flowchart illustrating main processes of an example of the treatment sequence when the cleaning fluid is discharged from the discharge ports 360d.

In this example, unlike Example 1 of the treatment sequence, after the process of developing with the developing fluid, the cleaning fluid is discharged from the discharge ports 360d of the hot plate 360 toward the rear surface side of the wafer W.

At Step S41, specifically, the cleaning fluid is discharged from the discharge ports 360d of the hot plate 360 toward the rear surface peripheral portion of the wafer W, for example, after the stop of the discharge of the developing fluid at Step S8 and before the wafer W is carried to the outside of the chamber 320. Further, at least one of the evacuation of the treatment space K1 through the central exhaust path 340 and the evacuation of the treatment space K1 through the outer peripheral exhaust path 350 is continued. This exposes the rear surface peripheral portion of the wafer W to the acid atmosphere containing the gas of the weak acid. Then, the development-time product adhering to the rear surface peripheral portion of the wafer W reacts with the gas of the weak acid and lowers in molecular weight, and then vaporizes by heat or the like. The vaporized substance is emitted to the outside of the treatment space K1 by the evacuation of the treatment space K1.

According to the treatment sequence in this example, even if the development-time product goes around and adheres to the rear surface peripheral portion of the wafer W during the process of developing with the developing fluid, the development-time product can be removed with the cleaning fluid.

The cleaning fluid may be supplied such that the ability to remove the resist (specifically, the metal-containing resist) is higher than that of the developing fluid supplied at the development at Step S7 and Step S8. Specifically, at least one of the following may be satisfied.
The cleaning fluid is higher in supply flow rate than the developing fluid.
The cleaning fluid is higher in temperature than the developing fluid.
The cleaning fluid is higher in concentration of the weak acid in the fluid than the developing fluid.
The weakly developing substance is not added to the mixed solution being the raw material in the cleaning fluid but the weakly developing substance is added to the mixed solution being the raw material in the developing fluid.

### Modification Example of the Treatment Sequence in the Case where the Cleaning Fluid is Discharged from the Discharge Ports 360d

In the above example, the process of discharging the cleaning fluid from the discharge ports 360d of the hot plate 360 toward the rear surface side of the wafer W (Step S41) is performed after the process of developing with the developing fluid. Instead of this, the process of discharging the cleaning fluid (Step S41) may be performed from the latter stage of the process of developing with the developing fluid.

Specifically, at Step S8, the discharge of the cleaning fluid from the discharge ports 360d of the hot plate 360 toward the rear surface side of the wafer W may be started during the discharge of the developing fluid from the shower head 330.

According to this modification example, the time from the completion of the process of developing with the developing fluid to the completion of the removal of the development-time product from the rear surface peripheral portion of the wafer W (namely, the cleaning of the rear surface peripheral portion of the wafer W) can be reduced.

### Another Example of the Vaporizer

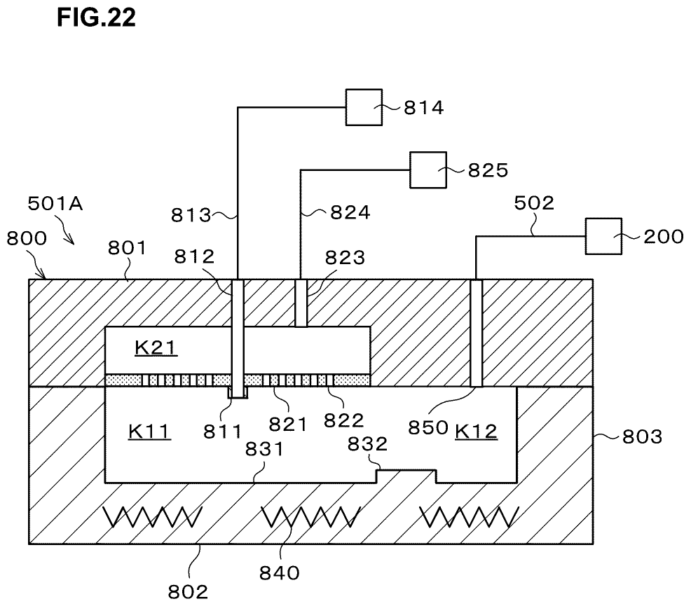

FIG. 22 is a longitudinal sectional view for explaining another example of the vaporizer.

A vaporizer 501A in FIG. 22 has a chamber 800 which collectively defines a later-explained mixing space K11 and an emission preparation space K12 adjacent to the mixing space K11 in the horizontal direction.

At a ceiling wall 801 of the chamber 800, a nozzle 811 as a discharge part which discharges the developing liquid is provided. Further, in the ceiling wall 801, a supply path 812 extending from the nozzle 811 is formed. To the supply path 812, a supply mechanism 814 for the developing liquid is connected through a supply pipe 813. The supply mechanism 814 has, for example, a supply source of the developing liquid and a supply equipment group including an opening/closing valve for controlling the distribution of the developing liquid and a flow rate regulating valve, which are not illustrated. This supply equipment group is controlled by the controller 100.

The amount of the developing liquid discharged at one time from the nozzle 811 is an amount corresponding to one development with the developing fluid and is a small amount, such as several milliliters.

Further, at the ceiling wall 801, a shower plate 821 formed with a plurality of discharge ports 822 is provided. The discharge ports 822 discharge an inert gas as a carrier gas to the mixing space K11 between the shower plate 821 and a later-explained diffusion part 831. The above nozzle 811 is attached, for example, to the shower plate 821 in a manner to extend downward from the center of a lower surface of the shower plate 821.

Further, in the ceiling wall 801, a diffusion space K21 communicating with the plurality of discharge ports 822, and a supply path 823 extending from the diffusion space K21 are formed. To the supply path 823, a supply mechanism 825 for the inert gas is connected through a supply path 824. The supply mechanism 825 has, for example, a supply source of the inert gas and a supply equipment group including an opening/closing valve and a flow rate regulating valve for controlling the distribution of the inert gas, which are not illustrated. This supply equipment group is controlled by the controller 100.

A surface of a bottom wall 802 of the chamber 800 facing the shower plate 821 constitutes the diffusion part 831.

The diffusion part 831 receives a small amount of the developing liquid discharged from the nozzle 811 and horizontally diffuses the developing fluid. The diffusion part 831 horizontally diffuses the developing fluid, for example, by the capillary phenomenon. For example, use of a member composed of continuously connecting fine structures for a portion corresponding to the diffusion part 831 of the bottom wall 802 makes it possible to horizontally diffuse the developing fluid by the capillary phenomenon in the diffusion part 831. Further, the diffusion part 831 may be the one whose surface is modified by plasma processing, hydrophilic coating, or the like in order to urge the diffusion of the developing liquid.

Further, at the bottom wall 802 of the chamber 800, a partition wall 832 is provided. The partition wall 832, the diffusion part 831, and a side wall 803 of the chamber 800 form a housing space for housing the developing liquid discharged from the nozzle 811.

The partition wall 832 partitions a leakage receiving space on the bottom wall 802 of the chamber 800 from the housing space. The leakage receiving space receives the developing liquid which cannot be housed in the housing space and leaks out. Note that a not-illustrated drain pipe which drains the developing liquid in the leakage receiving space to the outside may be provided. The drain pipe extends, for example, from the inside of the leakage receiving space and is attached to the ceiling wall 801.

Further, inside the bottom wall 802 of the chamber 800, a heater 840 for heating the developing liquid received by the diffusion part 831 and housed in the housing space is provided.

Further, at a portion of the ceiling wall 801 of the chamber 800 located above the above emission preparation space K12 adjacent to the above mixing space K11, an emission port 850 is provided. To the emission port 850, the supply path 502 is connected.

In the vaporizer 501A, the developing liquid discharged from the nozzle 811 and diffused in the diffusion part 831 is heated by the heater 840 to vaporize. The vaporized substance of the developing liquid is mixed with the inert gas discharged from the discharge ports 822 in the mixing space K11. The mixed gas of the vaporized substance of the developing liquid and the inert gas is supplied as the developing fluid to the developing unit 200 through the emission preparation space K12, the emission port 850, and the supply path 502.

### Modification Examples

In the above example, the discharge of the inert gas to the rear surface of the wafer W is performed from the discharge ports 360d provided separately from the through holes 372 into which the raising and lowering pins 370 are inserted. Instead of or in addition to the above, the discharge of the inert gas to the rear surface of the wafer W may be performed from the through holes 372.

Besides, the fluid containing the gas of the weak acid is used as the developing fluid in the above examples but, instead of this, fluid containing mist of the weak acid may be used or fluid containing both the gas of the weak acid and the mist of the weak acid may be used. In other words, the developing fluid according to this disclosure is fluid containing at least one of the gas of the weak acid and the mist of the weak acid.

Similarly, the fluid containing the gas of the weak acid is used as the cleaning fluid in the above examples but, instead of this, fluid containing the mist of the weak acid may be used or fluid containing both the gas of the weak acid and the mist of the weak acid may be used.

In the above examples, the distance between the wafer W and the main body part 360a of the hot plate 360 is adjusted by adjusting the raising and lowering pins 370 supporting the wafer W. Instead of this, the protrusions 360c of the hot plate 360 are configured to be changeable in height, so that the distance may be adjusted by adjusting the height of the protrusions 360c supporting the wafer W.

### Arrangement Example of Various Units in the Second Block G2, and an Arrangement Example and a Configuration Example of the Expansion Block Housing the Set Se of the Vaporizer 501 and the Concentration Sensor 550

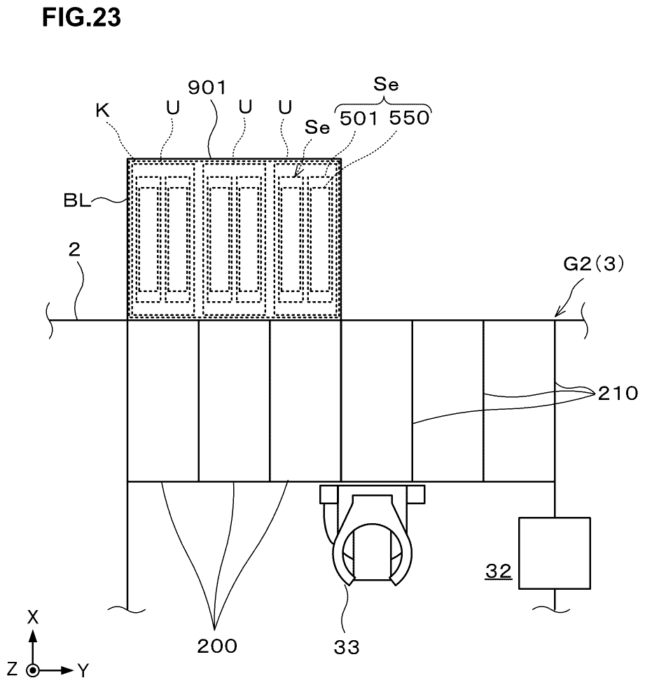

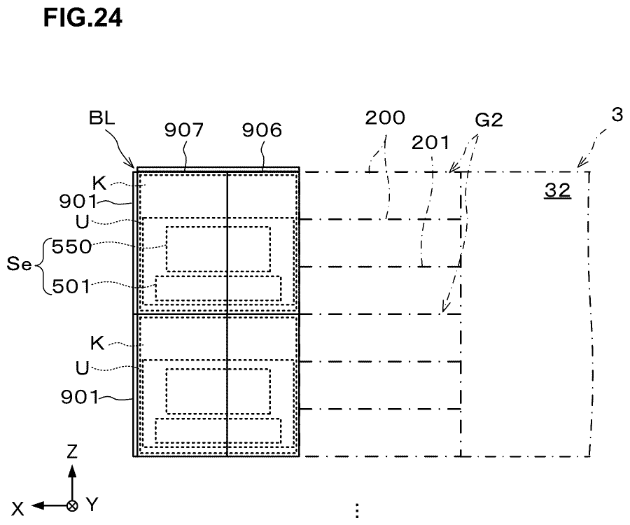

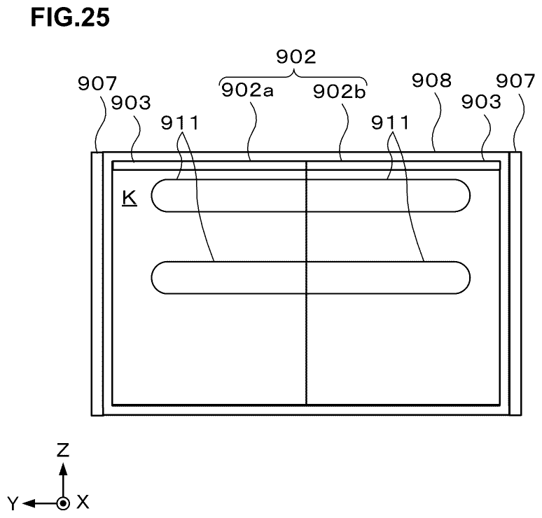

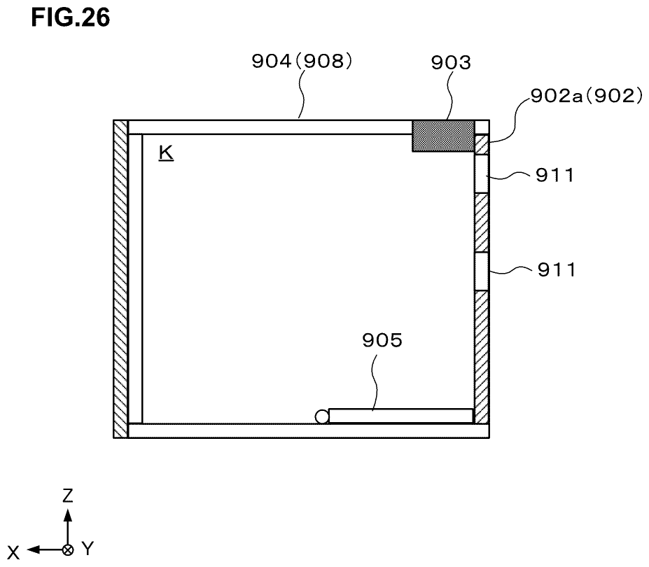

FIG. 23 is a view illustrating an arrangement example of various units in the second block G2 and an arrangement example of the expansion block. FIG. 24 is a side view illustrating a configuration example of the expansion block. FIG. 25 is a partially enlarged rear view illustrating the configuration example of the expansion block, illustrating a state where a later-explained rear panel 901 and unit U are detached. FIG. 26 is a partially enlarged sectional view illustrating a configuration example of the expansion block, illustrating the state where the unit U is detached.

As illustrated in FIG. 23, the developing units 200 are arranged along an apparatus width direction (Y-direction in the drawing) being the horizontal direction in the second block G2 being the treatment block of the treatment station 3. Further, the developing units 200 are provided only at a part in the apparatus width direction (Y-direction in the drawing) in the second block G2. Specifically, for example, they are provided only at a part on the cassette station 2 side (Y-direction negative side in the drawing) in the second block G2. The above “part” may be a half. Note that at other than the above “part” in the second block G2, for example, thermal treatment units 210 as thermal treatment apparatuses are provided. The thermal treatment units 210 are used for the PEB treatment and the POST treatment.

A plurality of developing units 200 are arranged also in a height direction (Z-direction in the drawing), namely, stacked. Specifically, for example, the second blocks G2 are stacked as illustrated in FIG. 24. Further, in each of the second blocks G2, a plurality of developing units 200 are arranged along in each of the height direction and the apparatus width direction (Y-direction in the drawing). For example, in each of the second blocks G2, two developing units 200 are arranged in the height direction and three developing units 200 are arranged in the apparatus width direction.

The set Se of the vaporizer 501 of the supply mechanism 500 for supplying the developing fluid to the developing unit 200 and the concentration sensor 550 corresponding to the vaporizer 501 is housed in an expansion block BL. Specifically, the expansion block BL has a housing space K and houses the vaporizer 501 and the concentration sensor 550 constituting the set Se in the same housing space K. More specifically, the expansion block BL houses two sets Se, which are combined into one unit U, in the same housing space K.

The expansion block BL is provided adjacent to a side opposite to the wafer carry region 32 side where the wafer carrier apparatus 33 as the carrier mechanism is arranged, namely, the rear surface side (X-direction positive side) in the second block G2.

Further, the expansion block BL is provided only in a region overlapping with a portion where the developing units 200 are provided in the second block G2 when viewed from the rear surface side (namely, in an X-direction view in FIG. 23). Specifically, for example, the expansion block BL is provided only in a region overlapping with a part on the cassette station 2 side (Y-direction negative side in the drawing) where the developing units 200 are provided in the second block G2 when viewed from the rear surface side.

Thus, the maintenance of the units (for example, the thermal treatment unit 210 and the like) in the portion where the developing units 200 are not provided in the second block G2 can be performed similarly to the case where the expansion block BL does not exist.

In the expansion block BL, as illustrated in FIG. 24, the treatment spaces K each for housing the above set Se are stacked. Each of the housing spaces K is located at the same height as the second block G2 where the developing units 200 to which the developing fluid is supplied from the set Se housed in the housing space K are provided.

The expansion block BL has a rear panel 901, a slide panel 902, an apparatus width direction guide 903, a depth direction guide 904, a stopper 905, a side panel 906, and an opening/closing panel 907 for each housing space K housing the set Se as illustrated in FIG. 24 to FIG. 26.

The rear panel 901 covers the rear surface side (X-direction positive side in the drawing) of the housing space K. The rear panel 901 does not need to be provided for each housing space K but may be provided to collectively cover the rear surface side of a plurality of treatment spaces K.

The slide panel 902 is a partition wall that separates the expansion block BL from the second block G2. The slide panel 902 is configured to be movable along the apparatus width direction (Y-direction in the drawing). Owing to the movement as above, the slide panel 902 is configured to be able to open the inside of the second block G2 to the rear surface side (X-direction positive side in the drawing).

The slide panel 902 concretely has, for example, a first slide panel 902a and a second slide panel 902b.

Both the first slide panel 902a and the second slide panel 902b are configured to be movable in the apparatus width direction (Y-direction in the drawing) and the depth direction (X-direction in the drawing). By moving the first slide panel 902a and the second slide panel 902b to closed positions, the first slide panel 902a and the second slide panel 902b cover almost the entire housing space K on the near side (X-direction negative side in the drawing) to separate the housing space K and the space in the second block G2 from each other. Further, by moving the first slide panel 902a and the second slide panel 902b to open positions, almost the entire portion of the second block G2 facing the housing space K is opened.

Each of the first slide panel 902a and the second slide panel 902b is provided with slits 911. Through the slits 911, for example, the supply pipe constituting the supply path 502 (see FIG. 9) for supplying the developing fluid from the set Se to the developing unit 200 is made to pass. Further, the slits 911 of the first slide panel 902a extend in the apparatus width direction such that the first slide panel 902a does not interfere with the above supply pipe when the first slide panel 902a is moved in the apparatus width direction (Y-direction in the drawing). This also applies to the slits 911 of the second slide panel 902b.

The apparatus width direction guides 903 are provided for the first slide panel 902a and the second slide panel 902b respectively, and support the first slide panel 902a and the second slide panel 902b respectively and guide the movements in the apparatus width direction (Y-direction in the drawing) of the first slide panel 902a and the second slide panel 902b. The apparatus width direction guide 903 for the first slide panel 902a and the apparatus width direction guide 903 for the second slide panel 902b may be integrated.

The depth direction guide 904 is provided for the first slide panel 902a and guides the movement in the depth direction (X-direction in the drawing) of the apparatus width direction guide 903. This guides the movement in the depth direction of the first slide panel 902a supported by the apparatus width direction guide 903. The depth direction guide 904 is similarly provided for the second slide panel 902b. At least a part of the depth direction guide 904 may also serve as a frame 908.

The stopper 905 is a member which presses the first slide panel 902a to prevent the first slide panel 902a from moving from the above closed position. The stopper 905 is similarly provided for the second slide panel 902b.

The side panel 906 is provided on each of one side and the other side in the apparatus width direction (Y-direction in the drawing) of the housing space K. Each side panel 906 covers the near side (X-direction negative side in the drawing) on the lateral side of the apparatus width direction (Y-direction in the drawing) of the housing space K.

The opening/closing panel 907 is provided on each of one side and the other side in the apparatus width direction (Y-direction in the drawing) of the housing space K. Each opening/closing panel 907 covers the deep side (X-direction positive side in the drawing) on the lateral side of the apparatus width direction (Y-direction in the drawing) of the housing space K. Further, each opening/closing panel 907 is configured to be able to open the housing space K to the lateral side of the apparatus width direction (Y-direction in the drawing). Specifically, for example, each opening/closing panel 907 is configured to be rotatable around its lower end portion as viewed from the rear surface side (X-direction positive side in the drawing).

To the frame 908, the rear panel 901, the side panels 906, and the opening/closing panels 907 are attached.

Note that an exhaust port (not illustrated) is provided, for example, at the bottom portion in the expansion block BL. The exhaust port exhausts gas in the expansion block BL, namely, evacuates each housing space K.

Further, in the expansion block BL, slit covers (not illustrated) may be provided which cover the slits 911 in a state where the first slide panel 902a and the second slide panel 902b are located at the closed positions. Further, a cover which blocks a gap other than the slits 911 and can make the inside of the expansion block BL and the inside of the second block G2 communicate with each other may be further provided.

<Maintenance of the Developing Unit 200 in the Case where the Expansion Block BL is Provided>

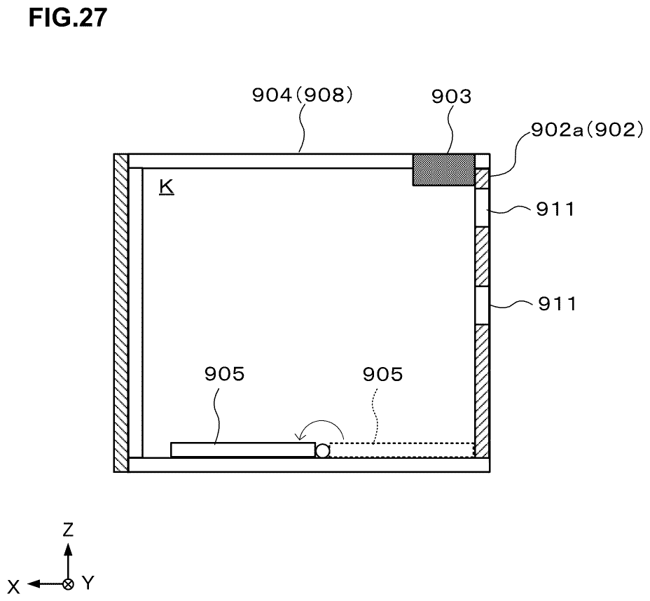

FIG. 27 to FIG. 30 are views for explaining an example of the maintenance of the developing unit 200 in the case where the expansion block BL is provided.

In the case where the expansion block BL is provided, in the maintenance of the developing unit 200, for example, the rear panel 901 of the housing space K corresponding to the developing unit 200 subject to the maintenance is detached first. Then, as illustrated in FIG. 27, the stopper 905 for the first slide panel 902a is released. The stopper 905 for the second slide panel 902b is also similarly released. Specifically, the first slide panel 902a and the second slide panel 902b are made into a state of being movable from the above closed positions to the deep side (X-direction positive side in the drawing). Besides, in the case where the above slit covers are provided, the slits 911 of the first slide panel 902a and the second slide panel 902b are brought into a state of not being covered by the slit covers.

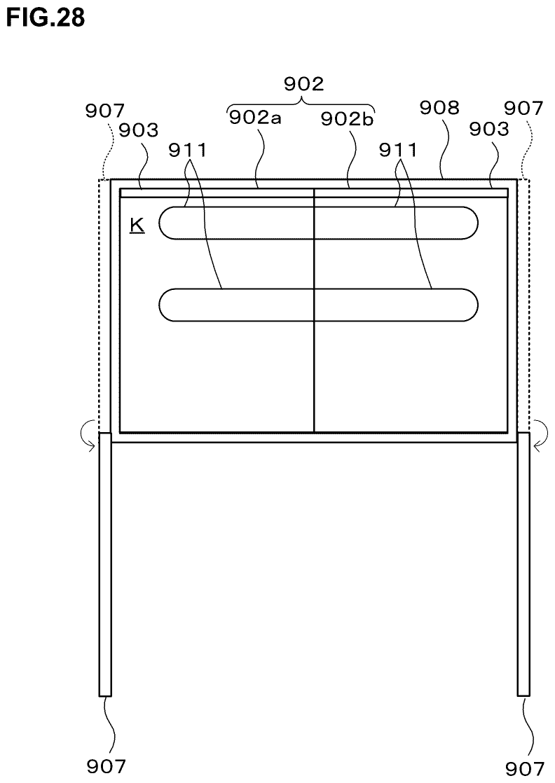

Thereafter, as illustrated in FIG. 28, the opening/closing panels 907 are rotated to open the lateral sides of the apparatus width direction (Y-direction in the drawing) of the housing space K.

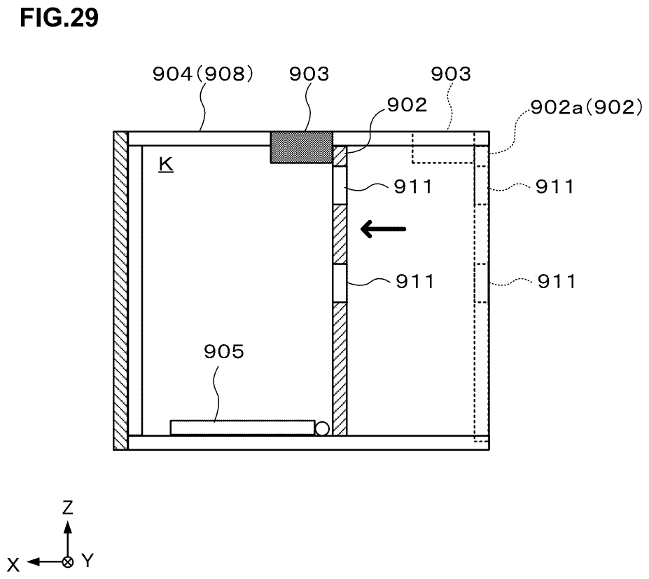

Further, as illustrated in FIG. 29, the first slide panel 902a is moved together with the apparatus width direction guide 903 to the rear surface side (X-direction positive side in the drawing) along the depth direction guide 904 and moved to the position of the opening/closing panel 907. The second slide panel 902b is also similarly moved.

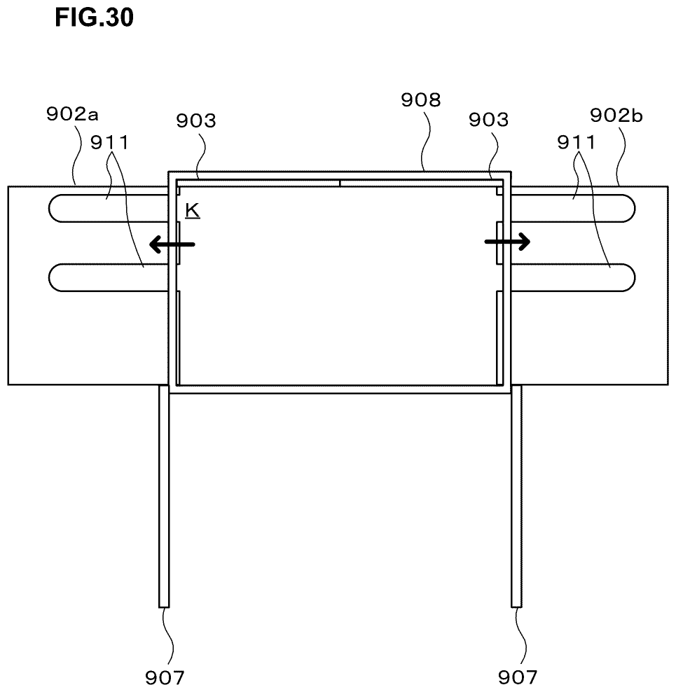

Then, the first slide panel 902a and the second slide panel 902b are moved to the opening positions along the apparatus width direction guides 903, namely, along the apparatus width direction (Y-direction in the drawing) as illustrated in FIG. 30. This opens the inside of the second block G2 to the rear surface side (X-direction positive side in the drawing). Note that the first slide panel 902a and the second slide panel 902b pass through a portion opened by the opening/closing panels 907 during the movement in the apparatus width direction.

Opening the inside of the second block G2 as above allows the operator to perform maintenance of the developing unit 200 inside the second block G2.

As explained above, two sets Se of the vaporizers 501 and the concentration sensors 550 corresponding to the vaporizers 501, in a state of being combined into one unit U, are housed in the housing space K. The two developing units 200 to which the developing fluid is supplied from the unit U are stacked one above the other as illustrated in FIG. 24. The upper end of each vaporizer 501 and the upper end of each concentration sensor 550 in the unit U are lower than the upper end of the developing unit 200 located at a lower tier of the two developing units 200 which are the supply destinations of the developing fluid by the unit U. Therefore, when the inside of the second block G2 is opened as above, the operator can perform maintenance of the developing unit 200 inside the second block G2 through a space facing the developing unit 200 located at the upper end of the two developing units 200 and located above the unit U. In other words, the operator can perform maintenance of the developing unit 200 inside the second block G2 without detaching the set Se included in the unit U.

### Another Arrangement Example of the Units in the Second Block G2, and Other Arrangement Example 1 and Another Configuration Example of the Expansion Block

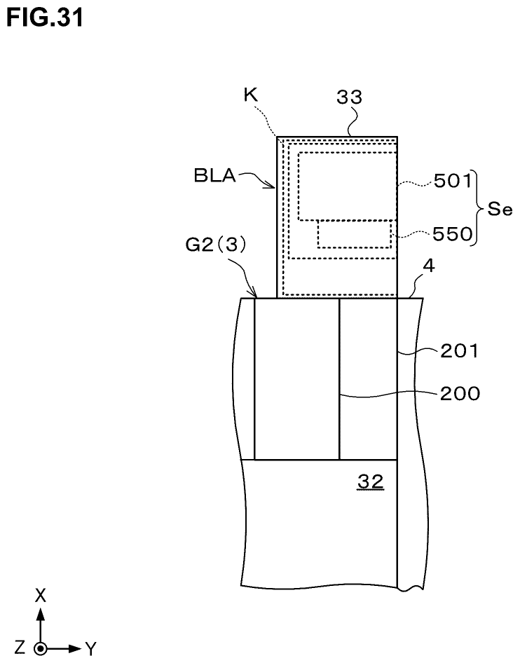

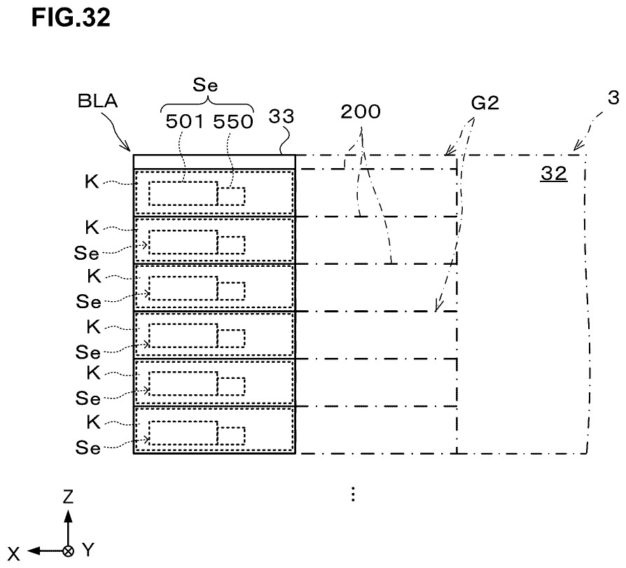

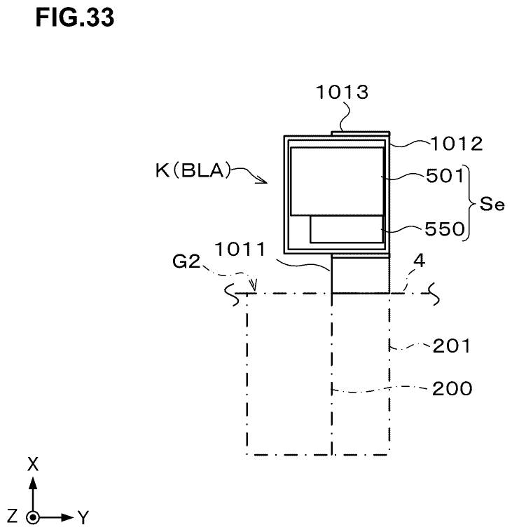

FIG. 31 is a view illustrating another arrangement example of the units in the second block G2 and Other arrangement example 1 of the expansion block. FIG. 32 is a side view illustrating another configuration example of the expansion block. FIG. 33 is a top view illustrating an internal configuration of the expansion block in FIG. 32, illustrating a state where a later-explained casing 1001 is detached.

As illustrated in FIG. 31, inside the second block G2 being the treatment block, the developing unit 200 and an electrical unit 201 corresponding to the developing unit 200 are arranged at the same height in the apparatus width direction (Y-direction in the drawing). Further, in the second block G2, the electrical unit 201 is provided at one end portion in the apparatus width direction (at an end portion on the Y-direction positive side in the example in the drawing).

Also in this example, a plurality of the developing units 200 are arranged in the height direction (Z-direction in the drawing), namely, stacked. Specifically, the second blocks G2 are stacked as illustrated in FIG. 32. Further, in each of the second blocks G2, one developing unit 200 is provided in the height direction. Note that in each of the second blocks G2, a plurality of (for example, two) developing units 200 are provided side by side in the apparatus width direction (Y-direction in the drawing). Further, the electrical unit 201 corresponding to the developing unit 200 is provided at an end portion in the apparatus width direction in the second block G2 where the developing unit 200 is provided and a position adjacent to the developing unit 200 in the apparatus width direction. In other words, the developing unit 200 is provided at the apparatus width direction central portion in the second block G2, and the electrical unit 201 is provided at the apparatus width direction end portion. This can improve the efficiency of carrying to the developing units 200.

Also in this example, the set Se of the vaporizer 501 of the supply mechanism 500 for supplying the developing fluid to the developing unit 200 and the concentration sensor 550 corresponding to the vaporizer 501 are housed in an expansion block BLA, and the expansion block BLA is provided adjacent to the rear surface side (X-direction positive side in the drawing) of the second block G2.

In the expansion block BLA, the treatment spaces K each for housing the set Se are stacked. Each of the housing spaces K is located at the same height as the second block G2 where the developing unit 200 to which the developing fluid is supplied from the set Se housed in the housing space K is provided.

The expansion block BLA has a casing 1001 in which the treatment spaces K are stacked. Further, the expansion block BLA has a base 1011, a mounting part 1012, and a guide 1013 in each of the housing spaces K housing the set Se as illustrated in FIG. 33.

On the base 1011, the mounting part 1012 is supported via the guide 1013.

At the mounting part 1012, the set Se of the vaporizer 501 and the concentration sensor 550 is mounted and fixed.

The guide 1013 supports the mounting part 1012 and guides the mounting part 1012 in the apparatus width direction (Y-direction in the drawing). In other words, the guide 1013 supports the mounting part 1012 in a manner of capable of moving it in the apparatus width direction (Y-direction in the drawing).

The guide 1013 allows the set Se of the vaporizer 501 and the concentration sensor 550 mounted on the mounting part 1012 to move in the apparatus width direction (Y-direction in the drawing).

By the guide 1013, the mounting part 1012 can move to a treatment position, a periodical maintenance position, and a heavy maintenance position.

In the state where the mounting part 1012 is located at the treatment position, the set Se mounted on the mounting part 1012 and the mounting part 1012 itself overlap with the corresponding developing unit 200 and the electrical unit 201 when viewed from the rear surface side (X-direction positive side in the drawing) as illustrated in FIG. 33. Further, in the state where the mounting part 1012 is located at the treatment position, the set Se mounted on the mounting part 1012 and the mounting part 1012 itself do not overlap with the block (interface station 4 in the example of the drawing) adjacent to the second block G2 where the corresponding developing unit 200 is provided when viewed from the rear surface side.

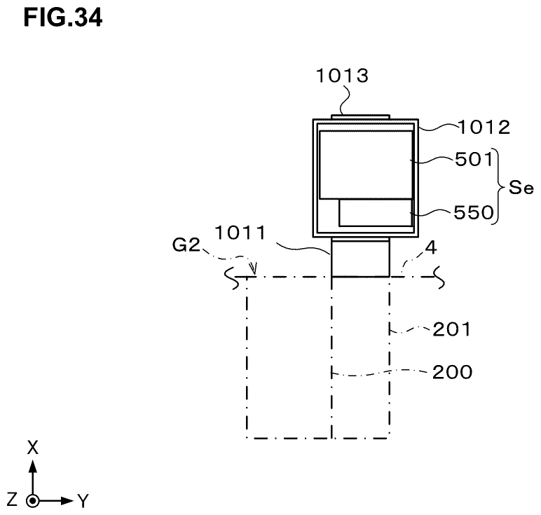

Also in the state where the mounting part 1012 is located at the periodical maintenance position, the set Se mounted on the mounting part 1012 and the mounting part 1012 itself overlap with the corresponding developing unit 200 and the electrical unit 201 when viewed from the rear surface side (X-direction positive side in the drawing) as illustrated in FIG. 34. However, in the state where the mounting part 1012 is located at the periodical maintenance position, the amount of the set Se mounted on the mounting part 1012 and the mounting part 1012 itself overlapping with the corresponding developing unit 200 when viewed from the rear surface side (X-direction positive side in the drawing) is smaller than that in the state where the mounting part 1012 is located at the treatment position. Accordingly, by locating the mounting part 1012 at the periodical maintenance position, the operator can easily perform maintenance on the developing unit 200 in the second block G2.

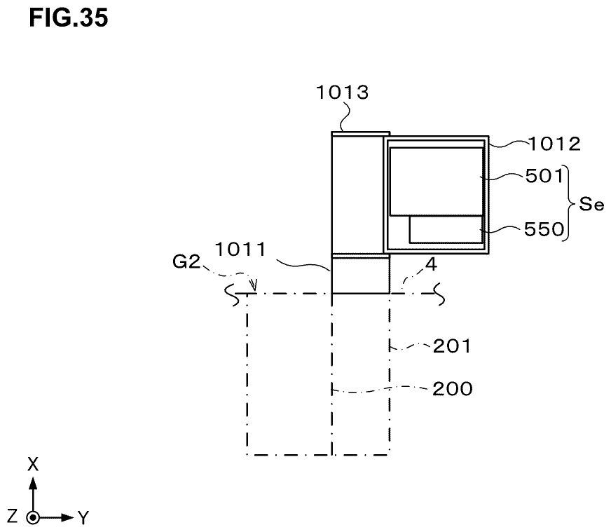

In the state where the mounting part 1012 is located at the heavy maintenance position, the set Se mounted on the mounting part 1012 and the mounting part 1012 itself do not overlap with the corresponding developing unit 200 at all when viewed from the rear surface side (X-direction positive side in the drawing) as illustrated in FIG. 35, and do not overlap with a part or the whole of the electrical unit 201. Accordingly, by locating the mounting part 1012 at the heavy maintenance position, the operator can easily perform maintenance not only on the developing unit 200 but also on the electrical unit 201 in the second block G2.

<Maintenance of the Units in the Second Block G2 in the Case where the Expansion Block BLA is Provided>

In the case where the expansion block BLA is provided, in the maintenance of the units in the second block G2, for example, a part or the whole of the casing 1001 of the expansion block BLA is detached first to bring the mounting part 1012 into a state of being movable in the apparatus width direction (Y-direction in the drawing).

For example, in the case where the maintenance target is the developing unit 200, the mounting part 1012 is moved from the treatment position to the periodical maintenance position. This can make a space on the rear surface side (X-direction positive side in the drawing) of the developing unit 200 in the second block G2, so that the operator can perform maintenance on the developing unit 200 through the space.

Besides, in the case where the maintenance target is the electrical unit 201, the supply pipe (not illustrated) constituting the supply path 502 (see FIG. 9) connecting the vaporizer 501 and the developing unit 200 is detached, and then the mounting part 1012 is moved to the heavy maintenance position. This can make a space on the rear surface side (X-direction positive side in the drawing) of the electrical unit 201 in the second block G2, so that the electrical unit 201 is taken out, for example, to the space and can be subjected to maintenance.

The reason why the above supply pipe is detached before the mounting part 1012 is moved to the heavy maintenance position is as follows. Specifically, the supply pipe is made short in order to improve the controllability and the responsibility of the concentration in the developing fluid and the flow rate of the developing fluid to be supplied to the developing unit 200 via the supply pipe, and therefore the mounting part 1012 cannot be moved to the heavy maintenance position with the supply pipe kept connected.

Note that when the mounting part 1012 is moved from the treatment position to the periodical maintenance position, the above supply pipe does not need to be detached.

### Another Configuration Example of the Wafer Treatment System and Other Arrangement Example 2 of the Expansion Block

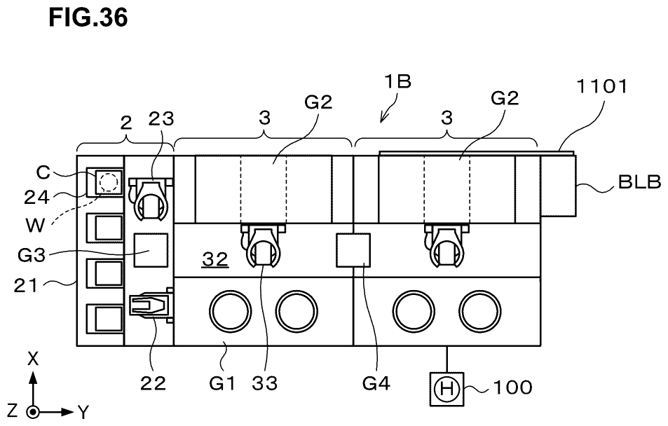

FIG. 36 is a view illustrating another configuration example of the wafer treatment system and Other arrangement example 2 of the expansion block.

In the above example, in the wafer treatment system 1 as the developing apparatus, the interface station 4 for delivering the wafer W between the treatment station 3 and the exposure apparatus is provided and connected with the exposure apparatus.

As illustrated in FIG. 36, a wafer treatment system 1B as the developing apparatus from which the interface station 4 may be omitted, does not need to be connected with the exposure apparatus.

In this case, an expansion block BLB housing the set Se of the vaporizer 501 and the sensor 550 is provided on a side opposite to the cassette station 2 side of the second block G2 in the treatment station 3 where the developing unit 200 is provided, namely, a side to which the interface station 4 has been connected (Y-direction positive side in the drawing). By providing the expansion block BLB at this position, it is possible to easily perform maintenance on the developing unit 200 in the second block G2.

Note that in this case, the vaporizer 501 in the expansion block BLB and the developing unit 200 in the second block G2 are connected via a supply pipe 1101 constituting the above supply path 502 (see FIG. 9). The supply pipe 1101 is provided, for example, along the rear surfaces (surfaces on the X-direction positive side in the drawing) of the expansion block BLB and the second block G2.

### Another Example of the Wafer Treatment System in the Case where the Exposure Apparatus is not Connected and an Arrangement Example of the Expansion Block in the Wafer Treatment System

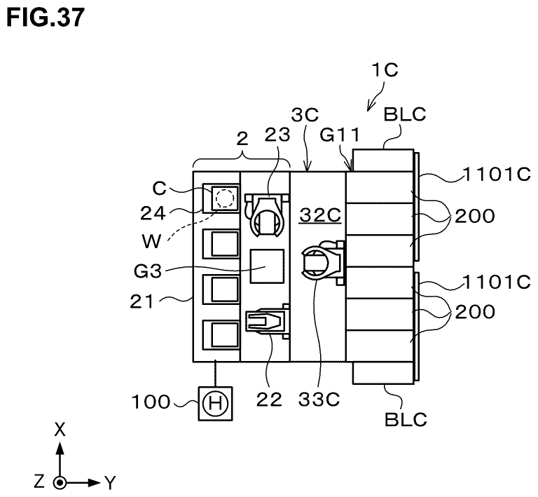

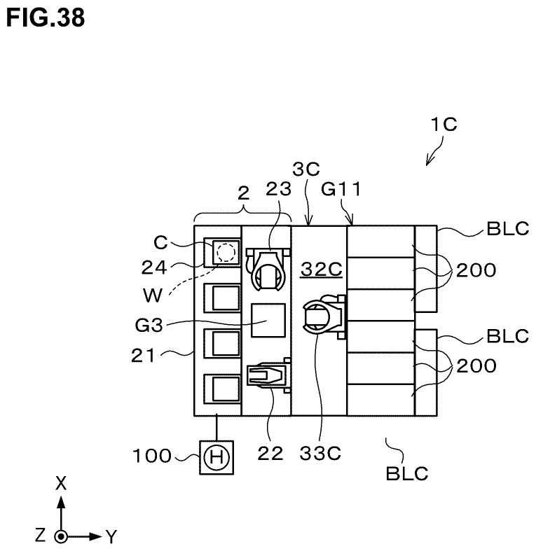

As illustrated in FIG. 37, in a wafer treatment system 1C as the developing apparatus to which the exposure apparatus is not connected, the above cassette station 2 and a treatment station 3C may be provided adjacent to each other in the apparatus width direction (Y-direction in the drawing) and a plurality of developing units 200 may be provided along the apparatus depth direction (X-direction in the drawing) in the treatment station 3C.

In the wafer treatment system 3C, specifically, for example, a block G11 as the treatment block is provided on the opposite side (Y-direction positive side in the drawing) to the cassette station 2 side, and a plurality of developing units 200 are provided in each of the apparatus depth direction (X-direction in the drawing) and the height direction (Z-direction in the drawing) in the block G11. Note that the treatment apparatuses other than the developing units 200 (for example, the thermal treatment apparatus for the PEB treatment and the thermal treatment apparatus for the POST treatment) may be provided in the block G11.

Further, a wafer carrier apparatus 33C is provided in a carry region 32C being a region on the cassette station 2 side in the treatment station 3C. The wafer carrier apparatus 33C carries the wafer W between the apparatus in the block G11 such as the developing unit 200 and the third block G3.

In the case where the treatment station 3C is configured as above, an expansion block BLC housing the set Se of the vaporizer 501 and the concentration sensor 550 is provided adjacent to the block G11 in the apparatus depth direction (X-direction in the drawing) in which the developing units 200 are arranged. Specifically, for example, the expansion block BLC for the developing units 200 provided on the deep side (X-direction positive side in the drawing) is provided adjacent to the deep side of the block G11 and the expansion block BLC for the developing units 200 provided on the near side (X-direction negative side in the drawing) is provided adjacent to the near side of the block G11. By providing the expansion blocks BLC at these positions, it is possible to easily perform maintenance on the developing units 200 from the rear surface being a surface on the opposite side (Y-direction positive side in the drawing) to the carry region 32C in the block G11.

Note that in this case, the vaporizer 501 in the expansion block BLC and the developing units 200 in the block G11 are connected via a supply pipe 1101C constituting the above supply path 502 (see FIG. 9). The supply pipe 1101C is provided, for example, along the rear surfaces (surfaces on the Y-direction positive side in the drawing) of the expansion block BLC and the block G11.

Further, in the example of the drawing, the expansion blocks BLC are provided adjacent to both the deep side and the near side of the block G11, namely, provided adjacent to both one side and the other side in the apparatus depth direction. However, in the case where the developing units 200 are provided only on the one side in the apparatus depth direction, the expansion block BLC may be provided adjacent to only the one side in the apparatus depth direction of the block G11.

Further, as illustrated in FIG. 37, the expansion block BLC may be provided adjacent to a side opposite to the carry region 32C side of the block G11, namely, the rear surface side (Y-direction positive side in the drawing) of the block G11. Specifically, for example, the expansion block BLC for the developing units 200 provided on the deep side (X-direction positive side in the drawing) may be provided adjacent to the rear surface side of a deep side portion of the block G11, and the expansion block BLC for the developing units 200 provided on the near side (X-direction negative side in the drawing) may be provided adjacent to the rear surface side of a near side portion of the block G11.

Note that the expansion blocks BLC are provided adjacent to rear surface sides of both the deep side portion and the near side portion of the block G11, namely, provided adjacent to rear surface sides both at one side portion and the other side portion in the apparatus depth direction in the example of the drawing. However, in the case where the developing units 200 are provided only on the rear surface side at one side portion in the apparatus depth direction, the expansion block BLC may be provided adjacent to the rear surface side only at the one side portion in the apparatus depth direction of the block G11.

The expansion block BLC may be configured similarly to the expansion block BLA explained using FIG. 23 and so on, or similarly to the expansion block BLA explained using FIG. 31 and so on.

The embodiments disclosed herein are examples in all respects and should not be considered to be restrictive. Various omissions, substitutions, and changes may be made in the embodiments without departing from the scope and the spirit of the attached claims. For example, configuration requirements of the above embodiments can be arbitrarily combined. From the arbitrary combination, the operations and effects about the configuration requirements relating to the combination can be naturally obtained, and other operations and other effects apparent to those skilled in the art are obtained from the description herein.

Besides, the effects explained herein are merely explanatory or illustrative in all respects and not restrictive. In other words, the technique relating to this disclosure can offer other effects apparent to those skilled in the art from the description herein in addition to or in place of the above effects.

Note that the following configuration examples also belong to the technical scope of this disclosure.
(1) A developing fluid supply apparatus comprising:
   a supply path connected to a developing part configured to develop a substrate on which a metal-containing resist film has been formed and which has been subjected to exposure processing, with a developing fluid containing at least one of gas and mist of a weak acid;
   a developing fluid generator configured to generate the developing fluid from a developing liquid; and
   a heating part configured to heat the developing fluid to be supplied to the developing part via the supply path.
(2) The developing fluid supply apparatus according to the (1), further comprising:
   a liquid flow rate sensor configured to measure a flow rate of the developing liquid to be supplied to the developing fluid generator;
   a gas flow rate sensor configured to measure a flow rate of a carrier gas to be supplied to the developing fluid generator; and
   a concentration sensor configured to measure a concentration of the at least one of gas and mist of the weak acid in the developing fluid.
(3) The developing fluid supply apparatus according to the (2), wherein
   a set of the developing fluid generator and the concentration sensor corresponding to the developing fluid generator is configured to be provided at a same height as the developing part at a supply destination of the developing fluid.
(4) The developing fluid supply apparatus according the (2) or (3), wherein
   a heating temperature of the developing liquid in the developing fluid generator, an amount of the developing liquid to be supplied to the developing fluid generator, or the flow rate of the carrier gas to be supplied to the developing fluid generator is adjusted based on a measurement result by the concentration sensor.
(5) The developing fluid supply apparatus according to the (1), further comprising:
   a concentration sensor configured to measure the at least one of gas and mist of the weak acid in the developing fluid; and
   a dilution path connected to the supply path and configured to supply a dilution gas for diluting the developing fluid supplied via the supply path, to the supply path, wherein
   a flow rate of the dilution gas to be supplied from the dilution path to the supply path is adjusted based on a measurement result by the concentration sensor.
(6) The developing fluid supply apparatus according to any one of the (1) to (5), wherein:
   the developing fluid generator comprises:
   a discharge part configured to discharge the developing liquid; and
   a diffusion part configured to receive the developing liquid discharged from the discharge part and horizontally diffuse the developing fluid.
(7) A developing apparatus comprising:
   the developing fluid supply apparatus according to the (3) and the developing part;
   a treatment block in which a plurality of the developing parts are arranged along an apparatus width direction being a horizontal direction;
   a carry region where a carrier mechanism configured to carry the substrate to the developing part is provided; and
   an expansion block adjacent to a rear surface side being an opposite side to the carry region side in the treatment block and configured to house the set in a same housing space.
(8) The developing apparatus according to the (7), wherein
   a partition wall separating the expansion block and the treatment block is configured to move along the apparatus width direction to be able to open an inside of the treatment block to the rear surface side.
(9) The developing apparatus according to the (7), wherein:
   the treatment block has an electrical unit at an end portion in the apparatus width direction; and
   the set is supported such that an amount thereof overlapping with the electrical unit and the developing part when viewed from the rear surface side is changeable.
(10) A developing fluid supply method comprising:
   generating a developing fluid containing at least one of gas and mist of a weak acid from a developing liquid;
   supplying the developing fluid to a developing part configured to develop a substrate on which a metal-containing resist film has been formed and which has been subjected to exposure processing; and
   heating the developing fluid to be supplied to the developing part.

According to this disclosure, it is possible to supply a developing fluid containing at least one of gas and mist of a weak acid suitable for the development of the metal-containing resist.

What is claimed is:

1. A developing fluid supply apparatus comprising:
a supply path connected to a developing part configured to develop a substrate on which a metal-containing resist film has been formed and which has been subjected to exposure processing, with a developing fluid containing at least one of gas and mist of a weak acid;
a developing fluid generator configured to generate the developing fluid from a developing liquid; and
a heating part configured to heat the developing fluid to be supplied to the developing part via the supply path.

2. The developing fluid supply apparatus according to claim 1, further comprising:
a liquid flow rate sensor configured to measure a flow rate of the developing liquid to be supplied to the developing fluid generator;
a gas flow rate sensor configured to measure a flow rate of a carrier gas to be supplied to the developing fluid generator; and
a concentration sensor configured to measure a concentration of the at least one of gas and mist of the weak acid in the developing fluid.

3. The developing fluid supply apparatus according to claim 2, wherein
a set of the developing fluid generator and the concentration sensor corresponding to the developing fluid generator is configured to be provided at a same height as the developing part at a supply destination of the developing fluid.

4. The developing fluid supply apparatus according to claim 2, wherein
a heating temperature of the developing liquid in the developing fluid generator, an amount of the developing liquid to be supplied to the developing fluid generator, or the flow rate of the carrier gas to be supplied to the developing fluid generator is adjusted based on a measurement result by the concentration sensor.

5. The developing fluid supply apparatus according to claim 1, further comprising:
a concentration sensor configured to measure the at least one of gas and mist of the weak acid in the developing fluid; and
a dilution path connected to the supply path and configured to supply a dilution gas for diluting the developing fluid supplied via the supply path, to the supply path, wherein
a flow rate of the dilution gas to be supplied from the dilution path to the supply path is adjusted based on a measurement result by the concentration sensor.

6. The developing fluid supply apparatus according to claim 1, wherein:
the developing fluid generator comprises:
a discharge part configured to discharge the developing liquid; and
a diffusion part configured to receive the developing liquid discharged from the discharge part and horizontally diffuse the developing fluid.

7. A developing apparatus comprising:
the developing fluid supply apparatus according to claim 3 and the developing part;
a treatment block in which a plurality of the developing parts are arranged along an apparatus width direction being a horizontal direction;
a carry region where a carrier mechanism configured to carry the substrate to the developing part is provided; and
an expansion block adjacent to a rear surface side being an opposite side to the carry region side in the treatment block and configured to house the set in a same housing space.

8. The developing apparatus according to claim 7, wherein
a partition wall separating the expansion block and the treatment block is configured to move along the apparatus width direction to be able to open an inside of the treatment block to the rear surface side.

9. The developing apparatus according to claim 7, wherein:
the treatment block has an electrical unit at an end portion in the apparatus width direction; and
the set is supported such that an amount thereof overlapping with the electrical unit and the developing part when viewed from the rear surface side is changeable.

10. A developing fluid supply method comprising:
generating a developing fluid containing at least one of gas and mist of a weak acid from a developing liquid;
supplying the developing fluid to a developing part configured to develop a substrate on which a metal-containing resist film has been formed and which has been subjected to exposure processing; and
heating the developing fluid to be supplied to the developing part.
